(19) United States
(12) Patent Application Publication
(10) Pub. No.: US 2026/0164957 A1
(43) Pub. Date: Jun. 11, 2026

(54) Display Substrate and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Tinghua SHANG, Beijing (CN); Yi ZHANG, Beijing (CN); Yang ZHOU, Beijing (CN); Hongwei MA, Beijing (CN); Huijuan YANG, Beijing (CN)

(21) Appl. No.: 18/705,995

(22) PCT Filed: Apr. 7, 2023
(86) PCT No.: PCT/CN2023/087080

§ 371 Date: Apr. 30, 2024

(51) Int. Cl. H10K 59/131

(52) U.S. Cl. CPC H10K 59/131

(57) ABSTRACT

Disclosed are a display substrate and a display apparatus. The display substrate includes a substrate, a plurality of sub-pixels, a plurality of first signal lines and a plurality of second signal lines, which are provided on the substrate, a sub-pixel includes a pixel circuit electrically connected with a first signal line, a first signal line includes at least one initial signal line, and a second signal line includes at least one initial connection line. The initial signal line extends along a first direction (D1), and the initial connection line extends along a second direction (D2), and the first direction (D1) intersects with the second direction (D2).

### CROSS-REFERENCE TO RELATED APPLICATION

The present application is a U.S. National Phase Entry of International Application No. PCT/CN2023/087080 having an international filing date of Apr. 7, 2023. The above-identified application is hereby incorporated by reference.

### TECHNICAL FIELD

The present disclosure relates to, but is not limited to, the field of display technologies, and more particularly, to a display substrate and a display apparatus.

### BACKGROUND

Organic Light Emitting Diodes (OLEDs) and Quantum dot Light Emitting Diodes (QLEDs) are active light emitting display devices and have advantages such as self-luminescence, wide viewing angle, high contrast ratio, low power consumption, extremely high response speed, lightness and thinness, flexibility, and low cost. With constant development in display technologies, a flexible display that uses an OLED or a QLED as a light emitting device and performs signal control by a Thin Film Transistor (TFT for short) has become the majority in the field of display at present.

### SUMMARY

The following is a summary of subject matter described in the present disclosure in detail. This summary is not intended to limit the protection scope of claims.

In a first aspect, the present disclosure provides a display substrate, including: a substrate and a plurality of sub-pixels, a plurality of first signal lines and a plurality of second signal lines, which are provided on the substrate, wherein a sub-pixel includes a pixel circuit electrically connected with the first signal lines, the first signal lines include at least one initial signal line, and second signal lines includes at least one initial connection line; the initial signal line extends along a first direction, the initial connection line extends along a second direction, and the first direction intersects with the second direction; the at least one initial signal line is in a one-to-one correspondence with the at least one initial connection line, and the initial signal line is electrically connected with the corresponding initial connection line.

In an exemplary implementation, the at least one initial signal line includes a first initial signal line and a second initial signal line, wherein the second initial signal line is located on a side of the first initial signal line away from the substrate.

In an exemplary implementation, the display substrate further includes a plurality of reset signal lines extending, at least partially, along the first direction; an orthographic projection of the first initial signal line on the substrate is located between an orthographic projection of the second initial signal line on the substrate and an orthographic projection of the reset signal line on the substrate, and is not overlapped with the orthographic projection of the second initial signal line on the substrate and the orthographic projection of the reset signal line on the substrate.

In an exemplary implementation, the display substrate further includes a plurality of light emitting signal lines extending, at least partially, along the first direction; an orthographic projection of the second initial signal line on the substrate is located between the orthographic projection of the first initial signal line on the substrate and an orthographic projections of light emitting signal lines on the substrate, and is not overlapped with the orthographic projection of the first initial signal line on the substrate and the orthographic projections of the light emitting signal lines on the substrate.

In an exemplary implementation, the at least one initial connection line includes a first initial connection line and a second initial connection line, wherein the first initial connection line and the second initial connection line are disposed in a same layer, a plurality of first initial connection lines are arranged along the first direction, and a plurality of second initial connection lines are arranged along the first direction; the first initial connection lines and the second initial connection lines are alternately arranged along the first direction, two first initial connection lines passes through, along a centerline of the second direction, a signal body line of a second initial connection line located between the two first initial connection lines; the first initial connection line is electrically connected with the first initial signal line through a via, and the second initial connection line is electrically connected with the second initial signal line through a via.

In an exemplary implementation, the pixel circuit includes a capacitor, and the capacitor includes a first plate and a second plate, wherein the second plate of the capacitor is located on a side of the first plate of the capacitor away from the substrate; an orthographic projection of the first initial signal line on the substrate is overlapped, at least partially, with an orthographic projection of the second plate of the capacitor on the substrate.

In an exemplary implementation, the second initial connection line includes a signal body line, a plurality of first signal connection portions, and a plurality of second signal connection portions; wherein the signal body line extends along the second direction, the first signal connection portions and the second signal connection portions extend along the first direction, the first signal connection portions and the second signal connection portions are connected with the signal body line, respectively, and the signal body line is connected with the second initial signal line; the first signal connection portions and the second signal connection portions are located on opposite sides of the signal body line, and are symmetrically disposed with respect to the signal body line.

In an exemplary implementation, an orthographic projection of the signal body line on the substrate is overlapped, at least partially, with the orthographic projection of the second plate of the capacitor on the substrate.

In an exemplary implementation, orthographic projections of the first signal connection portions and the second signal connection portions on the substrate are overlapped, at least partially, with the orthographic projection of the second initial signal line on the substrate, and are not overlapped with the orthographic projection of the reset signal line on the substrate.

In an exemplary implementation, pixel structures of pixel circuits of adjacent sub-pixels located in a same row are symmetrically disposed with respect to a virtual straight line extending along the second direction.

In an exemplary implementation, the display substrate further includes a plurality of data signal lines extending along the second direction, data signal lines connected to adjacent sub-pixels are disposed symmetrically with respect to a virtual straight line extending along the second direction; an orthographic projection of the first initial connection line on the substrate or the orthographic projection of the signal body line of the second initial connection line on the substrate is located between orthographic projections of two adjacent data signal lines on the substrate.

In an exemplary implementation, the display substrate includes a plurality of first scan signal lines which extend, at least partially, along the first direction, the orthographic projection of the reset signal line on the substrate is located between an orthographic projection of a first scan signal line on the substrate and the orthographic projection of the first initial signal line on the substrate; the reset signal line includes a first sub-reset signal line and a second sub-reset signal line electrically connected with each other; the first sub-reset signal line is disposed in a same layer as the first initial signal line, the second sub-reset signal line is disposed in a same layer as the second initial signal line, and an orthographic projection of the first sub-reset signal line on the substrate is overlapped, at least partially, with an orthographic projection of the second sub-reset signal line on the substrate.

In an exemplary implementation, the display substrate includes a plurality of second scan signal lines which extend, at least partially, along the first direction; orthographic projections of the second scan signal lines on the substrate are located between the orthographic projection of the first scan signal line on the substrate and the orthographic projection of the light emitting signal line on the substrate; the second scan signal line includes a first sub-scan signal line and a second sub-scan signal line electrically connected with each other; the first sub-scan signal line is disposed in a same layer as the first initial signal line, the second sub-scan signal line is disposed in a same layer as the second initial signal line, and an orthographic projection of the first sub-scan signal line on the substrate is overlapped, at least partially, with an orthographic projection of the second sub-scan signal line on the substrate.

In an exemplary implementation, the display substrate further includes a plurality of first power supply lines and a plurality of planarization portions, the sub-pixel further includes a light emitting device, the light emitting device includes a first electrode, and the pixel circuit includes an oxide transistor; the planarization portions are disposed between adjacent first power supply lines, and connected with the adjacent first power supply lines; orthographic projections of the planarization portions on the substrate is overlapped, at least partially, with the orthographic projections of the reset signal line, the first scan signal line, the second scan signal line, the active layer of the oxide transistor and the first electrode of the light emitting device on the substrate; at least one of the orthographic projections of the planarization portions on the substrate is overlapped, at least partially, with the orthographic projection of the first initial signal line on the substrate.

In an exemplary implementation, a plurality of annular regions are formed between the plurality of first power supply lines and the plurality of planarization portions; and at least two annular regions are in different shapes.

In an exemplary implementation, the display substrate includes a display region and a non-display region, and the display substrate further includes a third signal line located in the non-display region, the sub-pixels, the first signal line and the second signal line are located in the display region, the third signal line includes at least one initial power supply line, the initial power supply line extends, at least partially, along the second direction; the at least one initial power supply line is in one-to-one correspondence with the at least one initial signal line, and the initial power supply line is electrically connected with the corresponding initial signal line.

In an exemplary implementation, the display region includes a first side and a second side disposed opposite to each other, and the third signal line is located on at least one of the first side and the second side of the display region.

In an exemplary implementation, the display substrate further includes a drive structure layer disposed on the substrate; the drive structure layer includes a first semiconductor layer, a first conductive layer, a second conductive layer, a second semiconductor layer, a third conductive layer, a fourth conductive layer and a fifth conductive layer, which are stacked sequentially; the first conductive layer includes, at least, a first scan signal line, a light emitting signal line, and a first plate located in a capacitor of at least one sub-pixel; the second conductive layer includes, at least, a first initial signal line, a first sub-reset signal line of the reset signal line, a first sub-scan signal line of the second scan signal line, and a second plate located in the capacitor of the at least one sub-pixel; the third conductive layer includes, at least, a second sub-reset signal line of the reset signal line, a second sub-scan signal line of the second scan signal line, and the second initial signal line; the fourth conductive layer includes, at least, a first initial connection line and a second initial connection line; the fifth conductive layer includes, at least, a data signal line, a first power supply line, and a planarization portion.

In a second aspect, the present disclosure further provides a display apparatus, including the abovementioned display substrate.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic diagram of a planar structure of another display substrate.

FIG. 4A is a schematic diagram of an equivalent circuit of a pixel circuit.

FIG. 4B is a working timing diagram of the pixel circuit provided in FIG. 4A.

FIG. 5 is a schematic plan view of a display substrate according to an embodiment of the present disclosure.

FIG. 6 is a schematic diagram of a structure of a display substrate according to an embodiment of the present disclosure.

FIG. 7 is a schematic diagram 1 of a partial film of a display substrate according to an exemplary implementation.

FIG. 8 is a schematic diagram 2 of a partial film of a display substrate according to an exemplary implementation.

FIG. 9 is a schematic diagram 3 of a partial film of a display substrate according to an exemplary implementation.

FIG. 10 is a schematic diagram after a pattern of a shading layer is formed.

FIG. 11 is a schematic diagram of a pattern of a first semiconductor layer.

FIG. 12 is a schematic diagram after the pattern of the first semiconductor layer is formed.

FIG. 13 is a schematic diagram of a pattern of a first conductive layer.

FIG. 14 is a schematic diagram after the pattern of the first conductive layer is formed.

FIG. 15 is a schematic diagram of a pattern of a second conductive layer.

FIG. 16 is a schematic diagram after the pattern of the second conductive layer is formed.

FIG. 17 is a schematic diagram of a pattern of a second semiconductor layer.

FIG. 18 is a schematic diagram after the pattern of the second semiconductor layer is formed.

FIG. 19 is a schematic diagram of a pattern of a third conductive layer.

FIG. 20 is a schematic diagram after the pattern of the third conductive layer is formed.

FIG. 21 is a schematic diagram after a pattern of a seventh insulation layer is formed.

FIG. 22 is a schematic diagram of a pattern of a fourth conductive layer.

FIG. 23 is a schematic diagram after the pattern of the fourth conductive layer is formed.

FIG. 24 is a schematic diagram after a pattern of a first planarization layer is formed.

FIG. 25 is a schematic diagram of a pattern of a fifth conductive layer.

FIG. 26 is a schematic diagram after the pattern of the fifth conductive layer is formed.

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in a plurality of different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings of the embodiments of the present disclosure only involve structures involved in the embodiments of the present disclosure, and for other structures, reference may be made to conventional designs.

In the accompanying drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating orientation or positional relationships are used to illustrate positional relationships between the composition elements with reference to the drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

In the specification, “disposed in a same layer” refers to a structure formed by patterning two (or more than two) structures through a same patterning process, and their materials may be the same or different. For example, materials of precursors for forming a plurality of structures disposed in a same layer are the same, and final materials may be the same or different.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

A Low Temperature Poly-Silicon (LTPS for short) technology is used in a display substrate. The LTPS technology has advantages such as a high resolution, a high response speed, high brightness, a high aperture ratio, etc. Although it is favored by the market, the LTPS technology also has some defects, such as a relatively high production cost and relatively large power consumption, etc. At that time, a technical scheme of backplate formed by combining Low Temperature Poly-Silicon and Oxide (LTPO) emerges. Compared with the LTPS technology, in the LTPO technology, a leakage current is smaller, pixel point response is faster, and an additional layer of an oxide is added to a display substrate, which reduces energy consumption required for exciting pixel points, thus reducing power consumption during screen display. There are a plurality of initial signals in the display products using an LTPO technology to facilitate the adjustment of many nodes of the pixel circuit in the display products, but the plurality of initial signals need to be provided with a plurality of signal lines, and a voltage drop of the signal lines affects display uniformity and reduces the display effect of the display substrate.

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting device connected with the circuit unit, wherein the circuit unit may include a pixel circuit, and the pixel circuit may be connected with a scan signal line, a light emitting signal line, and a data signal line, respectively. In an exemplary implementation, the timing controller may provide the data driver with a grayscale value and a control signal which are suitable for a specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal, the scan start signal and the like from the timing controller. For example, the scan driver may sequentially provide a scan signal with an on-level pulse to the scan signal lines S1 to Sm. For example, the scan driver may be constructed in a form of a shift register and may generate a scan signal in a manner that a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3 . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

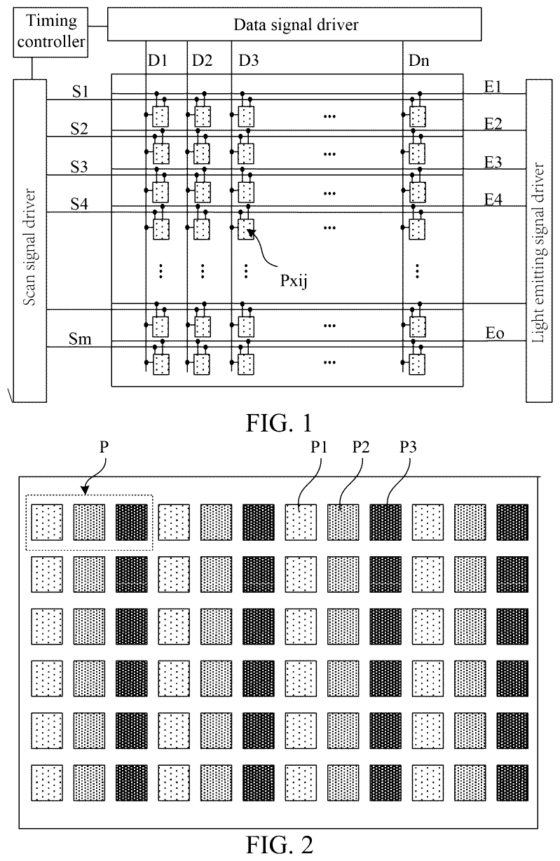

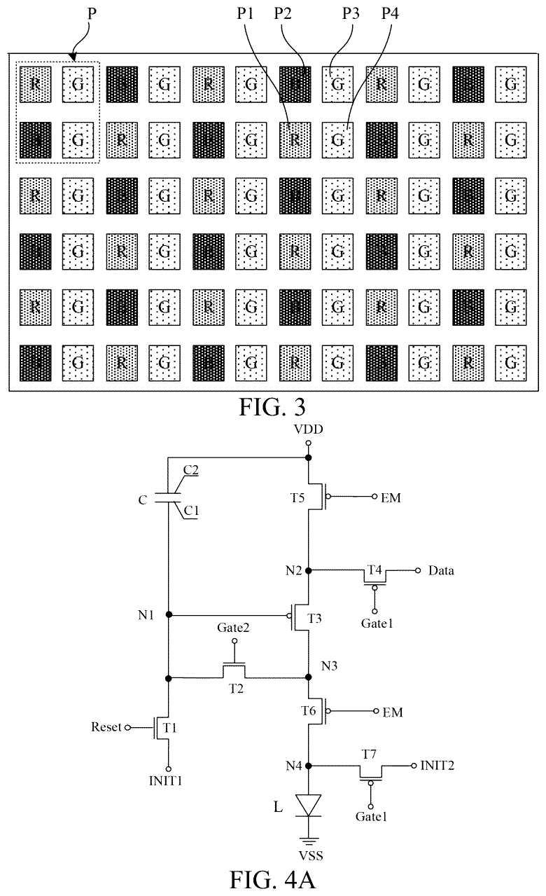

FIG. 2 is a schematic diagram of a planar structure of a display substrate. FIG. 3 is a schematic diagram of a planar structure of another display substrate. As shown in FIGS. 2 and 3, the display substrate may include a plurality of pixel units P arranged in a matrix, the plurality of pixel units P includes a first sub-pixel P1 emitting light in a first color, a second sub-pixel P2 emitting light in a second color, and at least one third sub-pixel P3 emitting light in a third color, and each of the first sub-pixel P1, the second sub-pixel P2, and the third sub-pixel P3 includes a pixel circuit and a light emitting device. The pixel circuits in the first sub-pixel P1, the second sub-pixel P2, and the third sub-pixel P3 each is connected with a scan signal line, a data signal line, and a light emitting signal line respectively, and the pixel circuit is configured to receive a data voltage transmitted by the data signal line under control of the scan signal line and the light emitting signal line, and output a corresponding current to the light emitting device. The light emitting devices in the first sub-pixel P1, the second sub-pixel P2, and the third sub-pixel P3 are respectively connected with respective pixel circuits of sub-pixels where light emitting devices are located, and the light emitting device is configured to emit light with a corresponding brightness in response to a current output by the pixel circuit of the sub-pixel where the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged in a manner of standing side by side horizontally, in a manner of standing side by side vertically, or in a delta-shaped arrangement, which is not limited in the present disclosure.

In an exemplary implementation, as shown in FIG. 2, a pixel unit may include three sub-pixels that may be arranged in a manner of standing side by side horizontally, in a manner of standing side by side vertically, or in a delta-shaped arrangement, which is not limited in the present disclosure. FIG. 2 is illustrated by taking standing side by side horizontally as an example.

In an exemplary implementation, as shown in FIG. 3, a pixel unit may include four sub-pixels which may include one first sub-pixel, one second sub-pixel, and two third sub-pixels. The four sub-pixels may be arranged in a manner of standing side by side horizontally, in a manner of standing side by side vertically, or in a manner of forming a square, which is not limited in the present disclosure. FIG. 3 illustrates four sub-pixels arranged in a form of square as an example.

In an exemplary implementation, the light emitting device may be an Organic Light Emitting Diode (OLED), including an electrode (anode), an organic light emitting layer, and a second electrode (cathode) which are stacked.

In an exemplary implementation, the organic emitting layer may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) that are stacked. In an exemplary implementation, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

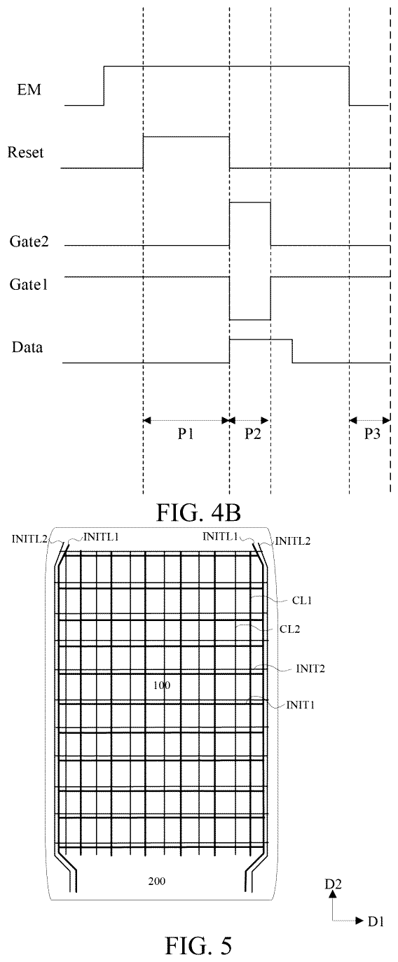

FIG. 4A is a schematic diagram of an equivalent circuit of a pixel circuit. In an exemplary implementation, the pixel circuit may be in a 3TIC, 4TIC, 5TIC, 5T2C, 6TIC, 7TIC, or 8TIC structure. As shown in FIG. 4A, the pixel circuit may include seven transistors (a first transistor T1 to a seventh transistor T7), and one capacitor C.

As shown in FIG. 4A, a gate electrode of the first transistor T1 is electrically connected with a reset signal line Reset, a first electrode of the first transistor T1 is electrically connected with a first initial signal line INIT1, and a second electrode of the first transistor T1 is electrically connected with a first node N1. A gate electrode of the second transistor T2 is electrically connected with a second scan signal line Gate2, a first electrode of the second transistor T2 is electrically connected with the first node N1, and a second electrode of the second transistor T2 is electrically connected with a third node N3. A gate electrode of the third transistor T3 is electrically connected with the first node N1, a first electrode of the third transistor T3 is electrically connected with a second node N2, and a second electrode of the third transistor T3 is electrically connected with the third node N3. A gate electrode of the fourth transistor T4 is electrically connected to the first scan signal line Gate1, a first electrode of the fourth transistor T4 is electrically connected with a data signal line Data, and a second electrode of the fourth transistor T4 is electrically connected with the second node N2. A gate electrode of the fifth transistor T5 is electrically connected with a light emitting signal line EM, a first electrode of the fifth transistor T5 is electrically connected with a first power supply line VDD, and a second electrode of the fifth transistor T5 is electrically connected with the second node N2. A gate electrode of the sixth transistor T6 is electrically connected to the light emitting signal line EM, a first electrode of the sixth transistor T6 is electrically connected with the third node N3, and a second electrode of the sixth transistor T6 is electrically connected with a fourth node N4. A gate electrode of the seventh transistor T7 is electrically connected with the first scan signal line Gate1, a first electrode of the seventh transistor T7 is electrically connected with a second initial signal line INIT2, and a second electrode of the seventh transistor T7 is electrically connected with the fourth node N4. A first plate C1 of the capacitor C is electrically connected with the first node N1, and a second plate C2 of the capacitor C is electrically connected with the first power supply line VDD.

In an exemplary implementation, the first transistor T1 may be referred to as a node reset transistor, and when a signal of the reset signal line Reset is an active level signal, an initial signal of the first initial signal line INIT1 is written to the first node N1.

In an exemplary implementation, the second transistor T2 may be referred to as a compensation transistor, and when a signal of the second scan signal line Gate2 is an active level signal, a signal at the third node N3 is written to the first node N1 to compensate a signal at the first node N1.

In an exemplary implementation, the third transistor T3 may be referred to as a drive transistor, and the third transistor T3 determines a magnitude of a drive current flowing between the first power supply line VDD and the second power supply line VSS according to a potential difference between the gate electrode and the first electrode of the third transistor T3.

In an exemplary implementation, the fourth transistor T4 may be referred to as a write transistor, which writes an initial signal of the data signal line Data to the second node N2 when a signal of the first scan signal line Gate1 is an active level signal.

In an exemplary implementation, the fifth transistor T5 and the sixth transistor T6 may be referred to as light emitting transistors. When a signal of the light emitting signal line EM is an active level signal, the fifth transistor T5 and the sixth transistor T6 enable the light emitting device to emit light by forming a drive current path between the first power supply line VDD and the second power supply line VSS.

In an exemplary embodiment, the seventh transistor T7 may be referred to as an anode reset transistor, and when a signal of the first scan signal line Gate1 is an active level signal, an initial signal of the second initial signal line INIT2 is written to the first electrode of the light emitting device L.

Transistors may be classified into N-type transistors and P-type transistors according to their characteristics. When a transistor is a P-type transistor, its turn-on voltage is a low-level voltage (e.g., 0V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation, for the first transistor T1 to the seventh transistor T7, low temperature poly silicon thin film transistors may be used, or oxide thin film transistors may be used, or both a low temperature poly silicon thin film transistor and an oxide thin film transistor may be used. An active layer of a low temperature poly silicon thin film transistor may be made of Low Temperature Poly silicon (LTPS), and an active layer of an oxide thin film transistor may be made of an oxide semiconductor (Oxide). A Low-temperature Poly Silicon thin film transistor has advantages such as a high mobility rate and fast charging, and an oxide thin film transistor has advantages such as a low leakage current. The Low Temperature Poly Silicon thin film transistor and the oxide thin film transistor are integrated on one display substrate to form a LTPO display substrate, and advantages of both the Low Temperature Poly Silicon thin film transistor and the oxide thin film transistor may be utilized, which may achieve low frequency drive, reducing power consumption, and improving display quality.

In an exemplary implementation, the first transistor T1 and the second transistor T2 are of a transistor type opposite to the third transistor T3 to the seventh transistor T7. For example, the first transistor T1 and the second transistor T2 may be N-type transistors, and the third transistors T3 to the ninth transistors T7 may be P-type transistors.

In an exemplary implementation, the first transistor T1 and the second transistor T2 may be oxide transistors, and the third transistor T3 to the seventh transistor T7 may be low-temperature poly silicon transistors.

In an exemplary implementation, a voltage value of the signal of the first initial signal line INIT1 may range from −2.5 volts to −3.5 volts. For example, the voltage value of the signal of the first initial signal line INIT1 may be −3 volts.

In an exemplary implementation, a voltage value of a signal of the second initial signal line INIT2 may range from −3.5 volts to −4.5 volts. For example, the voltage value of the signal of the second initial signal line INIT1 may be −4 volts.

According to the present disclosure, the first initial signal line INIT1 and the second initial signal line INIT2 can be disposed to achieve both a required brightness in a 0 grayscale mode and a required brightness in a highlight mode.

In an exemplary implementation, the light emitting device L may be electrically connected with the fourth node N4 and the second power supply line VSS, respectively.

In an exemplary implementation, the first power supply line VDD continuously provides a high-level signal, and the second power supply line VSS continuously provides a low-level signal.

FIG. 4B is a working timing diagram of the pixel circuit provided in FIG. 4A. An exemplary embodiment of the present disclosure is described below with reference to an operation process of the pixel circuit illustrated in FIG. 4A during a display stage. FIG. 4B illustrates an example in which the first transistor T1 and the second transistor T2 are N-type transistors, and the third transistor T3 to the seventh transistor T7 are P-type transistors. The pixel circuit in FIG. 4B includes the first transistor T1 to the seventh transistors T7, one capacitor C, and eight signal lines (the data signal line Data, the first scan signal line Gate1, the second scan signal line Gate2, the reset signal line Reset, the first initial signal line INIT1, the second initial signal line INIT2, the light emitting signal line EM, and the first power supply line VDD).

In conjunction with FIGS. 4A and 4B, the operation process of the pixel circuit may include following stages.

In a second stage P1, referred to as an initialization stage, the signal of the reset signal line Reset is a high-level signal, the first transistor T1 is turned on, and the signal of the first initial signal line INIT1 is written to the first node N1 through the turned-on first transistor T1, so as to initialize (reset) the first node N1, and empty a pre-stored voltage in the first node N1 to complete the initialization.

In a second stage P2, referred to as a data writing stage or a threshold compensation stage, the signal of the first scan signal line Gate1 is a low-level signal, the signal of the second scan signal line Gate2 is a low-level signal, and the data signal line Data outputs a data voltage. In this stage, because the first node N1 is a low-level signal, the third transistor T3 is turned on. The signal of the first scan signal line Gate1 is a low-level signal, both the fourth transistor T4 and the seventh transistor T7 are turned on, the signal of the second scanning signal Gate2 is a high-level signal, the second transistor T2 is turned on, the data voltage outputted from the data signal line Data is provided to the first node N1 through the turned-on fourth transistor T4, the second node N2, the turned-on third transistor T3, the third node N3 and the turned-on second transistor T2, a difference between the data voltage output from the data signal line Data and a threshold voltage of the third transistor T3 is charged into the capacitor C, until the voltage at the first node N1 is Vd−|Vth|, wherein Vd is the data voltage output from the data signal line Data, Vth is the threshold voltage of the third transistor T3. The seventh transistor T7 is turned on, and the signal of the second initial signal line INIT2 is written to the fourth node N4 through the turned-on seventh transistor T7, so as to initialize (reset) the first electrode of the light emitting element L, empty a pre-stored voltage inside the light emitting element L to complete the initialization.

In a third stage P3, referred to as a light emitting stage, the signal of the light emitting signal line EM is a low-level signal, both the fifth transistor T5 and the sixth transistor T6 are turned on, and a power supply voltage output from the first power supply line VDD provides a drive voltage to the first electrode of the light emitting device L through the turned-on fifth transistor T5, the third transistor T3, and the sixth transistor T6, to drive the light emitting device L to emit light.

In a driving process of the pixel circuit, a drive current flowing through the third transistor T3 (a drive transistor) is determined by a voltage difference between a gate electrode and a first electrode. Because the voltage at the first node N1 is Vd−|Vth|, the drive current of the third transistor T3 is as follows:

$$I = K ⋆ {( V gs - V th )}^{2} = K ⋆ {[ ( V dd - V d + \vert V th \vert ) - V th ]}^{2} = K ⋆ {[ ( V dd ‐ V d ) ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line Data, and Vdd is the power voltage output by the first power supply line VDD.

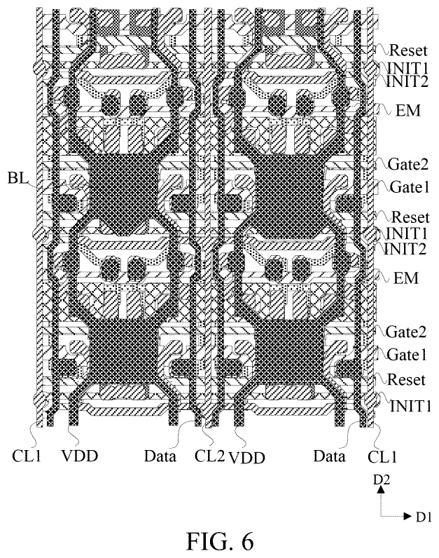

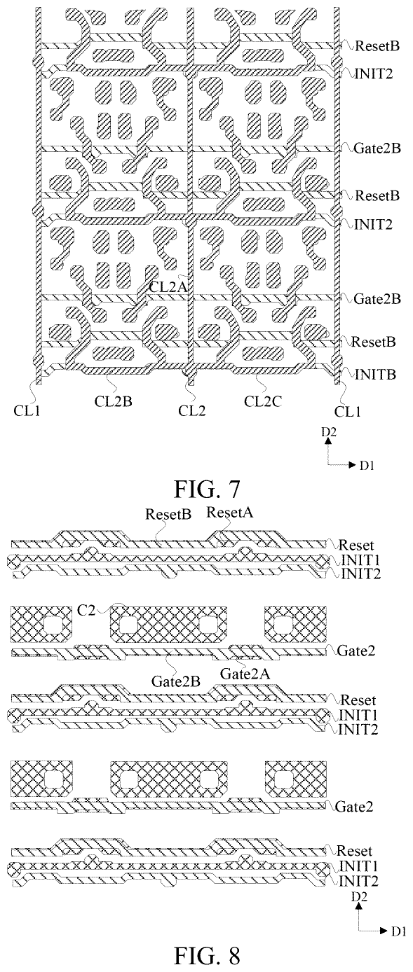

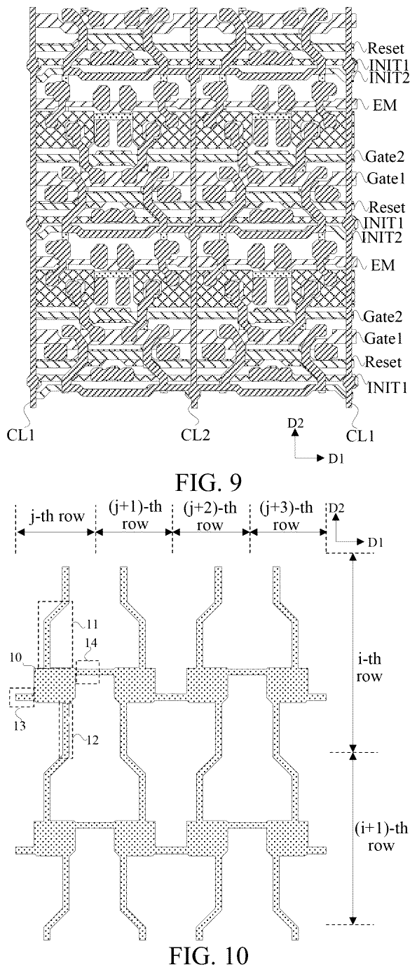

FIG. 5 is a schematic plan view of a display substrate according to an embodiment of the present disclosure, FIG. 6 is a schematic diagram of a structure of a display substrate according to an embodiment of the present disclosure, FIG. 7 is a schematic diagram 1 of a partial film of a display substrate according to an exemplary implementation, FIG. 8 is a schematic diagram 2 of a partial film of a display substrate according to an exemplary implementation, and FIG. 9 is a schematic diagram 3 of a partial film of a display substrate according to an exemplary implementation. As shown in FIGS. 5 to 9, the display substrate according to the embodiment of the present disclosure may include: a substrate and a plurality of sub-pixels, a plurality of first signal lines and a plurality of second signal lines, which are provided on the substrate, wherein a sub-pixel includes a pixel circuit electrically connected with a first signal line, the first signal lines include at least one initial signal line, and the second signal lines include at least one initial connection line; the initial signal line extends along a first direction D1, the initial connection line extends along a second direction, and the first direction D1 intersects with the second direction D2. FIGS. 6 to 9 are illustrated by taking sub-pixels in two rows and four columns as an example.

In an exemplary implementation, a quantity of the initial signal lines may be two, three or more, which may be determined according to a circuit configuration of a pixel circuit of a sub-pixel. FIGS. 5 to 9 are illustrated by taking the first signal lines including a first initial signal line INIT1 and a second initial signal line INIT2 as an example.

In an exemplary implementation, a quantity of the initial connection lines may be two, three or more, which may be the same as the quantity of the initial signal lines. FIGS. 5 to 9 are illustrated by taking the second signal lines including a first initial connection line CL1 and a second initial connection line CL2 as an example.

In an exemplary implementation, as shown in FIGS. 5 to 9, the at least one initial signal line is in a one-to-one correspondence with the at least one initial connection line, and an initial signal line is electrically connected with a corresponding initial connection line. For example, the first initial signal line INIT1 corresponds to the first initial connection line CL1, and is connected with the corresponding first initial connection line CL1. The second initial signal line INIT2 corresponds to the second initial connection line CL2, and is connected with the corresponding second initial connection line CL2.

In an exemplary implementation, signals between the at least one initial signal line may be the same, or may be different, which is not limited in the present disclosure.

In an exemplary implementation, the display substrate may be an LTPO display substrate.

In an exemplary implementation, the substrate may be a rigid substrate or a flexible substrate, wherein the rigid substrate may be, but is not limited to, one or more of glass and conductive foil. The flexible substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation, as shown in FIG. 5, the display substrate includes a display region 100 and a non-display region 200 surrounding at least one side of the display region. A plurality of sub-pixels, a plurality of first signal lines, and a plurality of second signal lines may be located in the display region 100.

In an exemplary implementation, the display region may be of a shape of square, rounded rectangle, or other shapes, which is not limited in the present disclosure.

The display substrate according to the embodiment of the present disclosure includes a substrate, a plurality of sub-pixels, a plurality of first signal lines and a plurality of second signal lines, which are provided on the substrate, wherein a sub-pixel includes a pixel circuit electrically connected with a first signal line, the first signal lines include at least one initial signal line, and the second signal lines include at least one initial connection line. The initial signal line extends along the first direction, and the initial connection line extends along the second direction, and the first direction intersects with the second direction. The at least one initial signal line is in a one-to-one correspondence with the at least one initial connection line, and an initial signal line is electrically connected with a corresponding initial connection line. According to the present disclosure, by providing the at least one initial signal line corresponding to the at least one initial connection line one to one, and the initial signal line is electrically connected with the corresponding initial connection line, so that any initial signal line and a corresponding initial connection line may form a mesh structure, which can reduce a voltage drop between the signal lines, improve display uniformity of the display substrate, and improve display effect of the display substrate.

In an exemplary implementation, as shown in FIGS. 6 to 9, the at least one initial signal line may include a first initial signal line INIT1 and a second initial signal line INIT2. The second initial signal line INIT2 may be located on a side of the first initial signal line INIT1 away from the substrate. The second initial signal line INIT2 may be located on the side of the first initial signal line INIT1 away from the substrate, which may reduce an area occupied by the sub-pixels to optimize a layout of the display substrate.

In an exemplary implementation, as shown in FIGS. 6 to 9, the display substrate may further include a plurality of reset signal lines “Reset”, wherein the reset signal lines “Reset” extend, at least partially, in the first direction D1.

In an exemplary implementation, as shown in FIGS. 6 to 9, an orthographic projection of the first initial signal line INIT1 on the substrate is located between an orthographic projection of the second initial signal line INIT2 on the substrate and an orthographic projection of the reset signal line Reset on the substrate, and is not overlapped with the orthographic projection of the second initial signal line INIT2 on the substrate and the orthographic projection of the reset signal line Reset on the substrate. The non-overlapping of the orthographic projection of the first initial signal line INIT1 on the substrate with the orthographic projection of the second initial signal line INIT2 on the substrate or the orthographic projection of the reset signal line Reset on the substrate can reduce an overlapping region between films, thereby reducing a parasitic capacitance.

In an exemplary implementation, the reset signal line Reset may be of a double-layer structure.

In an exemplary implementation, as shown in FIGS. 6 to 9, the display substrate may further include a plurality of light emitting signal lines EM extending, at least partially, in the first direction D1.

In an exemplary implementation, as shown in FIGS. 6 to 9, the orthographic projection of the second initial signal line INIT2 on the substrate is located between the orthographic projection of the first initial signal line INIT1 on the substrate and an orthographic projection of a light emitting signal line EM on the substrate, and is not overlapped with the orthographic projection of the first initial signal line INIT1 on the substrate, or the orthographic projection of the light emitting signal line EM on the substrate. The non-overlapping of the orthographic projection of the second initial signal line INIT2 on the substrate with the orthographic projection of the first initial signal line INIT1 on the substrate or the orthographic projection of the light emitting signal line EM on the substrate can reduce an overlapping area between the films, thereby reducing a parasitic capacitance.

In an exemplary implementation, as shown in FIGS. 6 to 9, at least one initial connection line includes a first initial connection line CL1 and a second initial connection line CL2. The first initial connection line CL1 and the second initial connection line CL2 are disposed in a same layer.

In an exemplary implementation, a plurality of first initial connection lines CL2 are arranged along the first direction D1, and a plurality of second initial connection lines CL2 are arranged along the first direction D1.

In an exemplary implementation, as shown in FIGS. 6 to 9, the first initial connection lines CL1 and the second initial connection lines CL2 are arranged alternately. That is, one second initial connection line is located between two first initial connection lines.

In an exemplary implementation, as shown in FIGS. 6 to 9, a centerline of two first initial connection lines CL1 along the second direction D2 may pass through a signal body line CL2A of a second initial connection line CL2 located between the two first initial connection lines.

In an exemplary implementation, as shown in FIGS. 6 to 9, the first initial connection line CL1 is electrically connected to the first initial signal line INIT1 through a via, and the second initial connection line CL2 is electrically connected to the second initial signal line INIT2 through a via.

In an exemplary implementation, as shown in FIGS. 6 to 9, the pixel circuit includes a capacitor including a first plate and a second plate, wherein the second plate C2 of the capacitor is located on a side of the first plate of the capacitor away from the substrate.

In an exemplary implementation, as shown in FIGS. 6 to 9, an orthographic projection of the first initial signal line INIT1 on the substrate is overlapped, at least partially, with an orthographic projection of the second plate C2 of the capacitor on the substrate.

In an exemplary implementation, as shown in FIGS. 6 to 9, at least one second initial connection line CL2 may include a signal body line CL2A, a plurality of first signal connection portions CL2B, and a plurality of second signal connection portions CL2C. The signal body line CL2A extends along the second direction D2, the first signal connection portion CL2B and the second signal connection portion CL2C extend along the first direction D1, each of the first signal connection portion CL2B and the second signal connection portion CL2C is connected with the signal body line CL2A, and the signal body line CL2A is connected with the second initial signal line INIT2.

In an exemplary implementation, as shown in FIGS. 6 to 9, the first signal connection portion CL2B and the second signal connection portion CL2C are located on opposite sides of the signal body line CL2A, and are disposed symmetrically with respect to the signal body line CL2A.

In an exemplary implementation, as shown in FIGS. 6 to 9, an orthographic projection of the signal body line CL2A on the substrate is overlapped, at least partially, with the orthographic projection of the second plate C2 of the capacitor on the substrate.

In an exemplary implementation, orthographic projections of the first signal connection portion CL2B and the second signal connection portion CL2C on the substrate are overlapped, at least partially, with the orthographic projection of the second initial signal line INIT2 on the substrate, and are not overlapped with the orthographic projection of the reset signal line Reset on the substrate.

According to the present disclosure, the orthographic projections of the first signal connection portion CL2B and the second signal connection portion CL2C on the substrate are overlapped, at least partially, the orthographic projection of the second initial signal line INIT2 on the substrate, which can increase an area proportion of a blank region without signal lines in the display substrate, such that transmittance of visible light in the display substrate can be improved.

According to the present disclosure, the orthographic projections of the first signal connection portion CL2B and the second signal connection portion CL2C are not overlapped with the orthographic projection of the reset signal line Reset on the substrate, which reduces an area of an overlapping region of a film where the first signal connection portion CL2B and the second signal connection portion CL2C are located and a film where the reset signal line Reset is located, avoids a short circuit risk between the reset signal line and the second initial connection line caused by protrusion of the reset signal line caused by dust particles when the second initial connection line is disposed on the reset signal line, thereby avoiding display defect caused by the short circuit, and improving reliability of the display substrate.

In an exemplary implementation, as shown in FIGS. 6 to 9, pixel structures of pixel circuits in adjacent sub-pixels located in a same row are symmetrically disposed with respect to a virtual straight line extending along the second direction D2, which can enable the adjacent sub-pixels to share a partial structure, reduce an occupied space of the pixel circuits to increase a lateral space, so as to provide a space for the arrangement of the second signal line, and optimize a wiring space of the display substrate.

In an exemplary implementation, as shown in FIGS. 6 to 9, the display substrate may further include a plurality of data signal lines “Data” extending along the second direction D2.

In an exemplary implementation, as shown in FIGS. 6 to 9, data signal lines Data connected to adjacent sub-pixels are disposed symmetrically with respect to the virtual straight line extending along the second direction D2.

In an exemplary implementation, as shown in FIGS. 6 to 9, an orthographic projection of the first initial connection line CL1 on the substrate or an orthographic projection of the signal body line CL2A of the second initial connection line CL2 on the substrate are located between orthographic projections of two adjacent data signal lines Data on the substrate. That is, the first initial connection line CL1, and the signal body line CL2A of the second initial connection line CL2 are interspersed between the data signal lines Data, which can ensure integrity of the structure included in a film where the Data signal lines are located (for example, the first electrodes and the second electrodes of the first transistor, the second transistor and the third transistor), can improve a shielding effect and a covering effect, and is suitable for a high-resolution display substrate.

In an exemplary implementation, as shown in FIGS. 6 to 9, the display substrate may further include a plurality of first scan signal lines Gate1 extending, at least partially, along the first direction D1.

In an exemplary implementation, as shown in FIGS. 6 to 9, the orthographic projection of the reset signal line Reset on the substrate is located between an orthographic projection of the first scan signal line Gate1 on the substrate and an orthographic projection of the first initial signal line INIT1 on the substrate.

In an exemplary implementation, as shown in FIGS. 6 to 9, the reset signal line Reset may include a first sub-reset signal line ResetA and a second sub-reset signal line ResetB electrically connected with each other. For example, the first sub-reset signal line ResetA and the second sub-reset signal line ResetB may be connected in the non-display region.

In an exemplary implementation, as shown in FIGS. 6 to 9, the first sub-reset signal line ResetA may be disposed in a same layer as the first initial signal line INIT1, the second sub-reset signal line ResetB may be arranged in a same layer as the second initial signal line INIT2, and an orthographic projection of the first sub-reset signal line ResetA on the substrate is overlapped, at least partially, with an orthographic projection of the second sub-reset signal line ResetB on the substrate.

In an exemplary implementation, as shown in FIGS. 6 to 9, the display substrate may further include a plurality of second scan signal lines Gate2 extending, at least partially, along the first direction D1.

In an exemplary implementation, the second scan signal line Gate2 may be of a double-layer structure.

In an exemplary implementation, as shown in FIGS. 6 to 9, an orthographic projection of the second scan signal line Gate2 on the substrate is located between the orthographic projection of the first scan signal line Gate1 and the orthographic projection of the light emitting signal line EM on the substrate.

In an exemplary implementation, as shown in FIGS. 6 to 9, the second scan signal line Gate2 may include a first sub-scan signal line Gate2A and a second sub-scan signal line Gate2B electrically connected with each other. For example, the first sub-scan signal line Gate2A and the second sub-scan signal line Gate2B may be connected in the non-display region.

In an exemplary implementation, as shown in FIGS. 6 to 9, the first sub-scan signal line Gate2A is disposed in a same layer as the first initial signal line INIT1, the second sub-scan signal line Gate2B is disposed in a same layer as the second initial signal line INIT2, and an orthographic projection of the first sub-scan signal line Gate2A on the substrate is overlapped, at least partially, with an orthographic projection of the second sub-scan signal line Gate2B on the substrate.

In an exemplary implementation, as shown in FIGS. 6 to 9, the display substrate may further include a plurality of first power supply lines VDD and a plurality of planarization portions BL. The sub-pixel further includes a light emitting device, wherein the light emitting device includes a first electrode, and the pixel circuit includes an oxide transistor.

In an exemplary implementation, the oxide transistor includes a first transistor and a second transistor.

In an exemplary implementation, as shown in FIGS. 6 to 9, first power supply lines connected to adjacent sub-pixels are disposed symmetrically with respect to the virtual straight line extending along the second direction D2.

In an exemplary implementation, a first power supply line VDD is connected with one adjacent power supply line, and is spaced away from another adjacent power supply line, and two data signal lines Data are disposed between the two first power supply lines VDD spaced away from each other.

In an exemplary implementation, as shown in FIGS. 6 to 9, the planarization portion BL is disposed between adjacent first power supply lines VDD, and is connected to the adjacent first power supply lines VDD.

In an exemplary implementation, as shown in FIGS. 6 to 9, an orthographic projection of the planarization portion BL on the substrate is overlapped, at least partially, with orthographic projections of the reset signal line Reset, the first scan signal line Gate1, the second scan signal line Gate2, an active layer of the oxide transistor, and the first electrode of the light emitting device on the substrate. According to the present disclosure, flatness of the first electrode of the light emitting device can be improved by providing the planarization portion, so as to improve the display effect of the display substrate.

In an exemplary implementation, as shown in FIGS. 6 to 9, an orthographic projection of at least one planarization portion BL on the substrate is overlapped, at least partially, with the orthographic projection of the first initial signal line INIT1 on the substrate.

In an exemplary implementation, as shown in FIGS. 6 to 9, a plurality of annular regions are formed between a plurality of first power supply lines VDD and a plurality of planarization portions BL.

In an exemplary implementation, as shown in FIGS. 6 to 9, at least two annular regions are of different shapes.

In an exemplary implementation, the light emitting device may include a first light emitting device, a second light emitting device, a third light emitting device, and a fourth light emitting device, wherein the first light emitting device emits red light, the second light emitting device emits blue light, and the third and fourth light emitting devices emits green light.

In an exemplary implementation, an area of a first electrode of the second light emitting device is larger than an area of a first electrode of the first light emitting device, and areas of a first electrode of the third light emitting device and a first electrode of the fourth light emitting device are smaller than the area of the first electrode of the first light emitting device.

In an exemplary implementation, as shown in FIG. 5, the display substrate includes the display region 100 and the non-display region 200, and further includes a third signal line located in the non-display region, wherein the sub-pixels, the first signal lines and the second signal lines are located in the display region, the third signal line includes at least one initial power supply line extends, at least partially, along the second direction D2. The at least one initial power supply line is in a one-to-one correspondence with the at least one initial signal line, and an initial power supply line is electrically connected with a corresponding initial signal line. FIG. 5 is illustrated by taking the third signal line including a first initial power supply line INITL1 and a second initial power supply line INITL2 as an example. For example, the first initial power supply line INITL1 corresponds to the first initial signal line INIT1, and is connected to the first initial signal line INIT1. The second initial power supply line INITL2 corresponds to the second initial signal line INIT2, and is connected to the second initial signal line INIT2.

In an exemplary implementation, as shown in FIG. 5, the display region 100 includes a first side and a second side disposed oppositely, and the third signal line is located on at least one of the first side and the second side of the display region. FIG. 5 is illustrated by taking the third signal line located on the first side and the second side as an example.

In an exemplary implementation, the display substrate may further include a drive structure layer disposed on the substrate. The drive structure layer includes a first semiconductor layer, a first conductive layer, a second conductive layer, a second semiconductor layer, a third conductive layer, a fourth conductive layer and a fifth conductive layer, which are stacked sequentially.

The first conductive layer includes, at least, a first scan signal line Gate1, a light emitting signal line EM, and a first plate located in a capacitor of at least one sub-pixel.

The second conductive layer includes, at least, a first initial signal line INIT1, a first sub-reset signal line ResetA of the reset signal line Reset, a first sub-scan signal line Gate2A of the second scan signal line Gate2, and a second plate C2 located in the capacitor of the at least one sub-pixel.

The second semiconductor layer includes, at least, an active layer of an oxide transistor.

The third conductive layer includes, at least, a second sub-reset signal line ResetB of the reset signal line Reset, a second sub-scan signal line Gate2B of the second scan signal line Gate2, and the second initial signal line INIT2.

The fourth conductive layer includes, at least, the first initial connection line CL1 and the second initial connection line CL2.

The fifth conductive layer includes, at least, the data signal line Data, the first power supply line VDD, and the planarization portion BL.

In an exemplary implementation, the drive structure layer may further include a light shielding layer, a first insulation layer, a second insulation layer, a third insulation layer, a fourth insulation layer, a fifth insulation layer, a sixth insulation layer, a seventh insulation layer, an eighth insulation layer, a first planarization layer, and a second planarization layer. The light shielding layer is located on a side of the first semiconductor layer close to the substrate, the first insulation layer is located between the substrate and the light shielding layer, the second insulation layer is located between the light shielding layer and the first semiconductor layer, the third insulation layer is located between the first semiconductor layer and the first conductive layer, the fourth insulation layer is located between the first conductive layer and the second conductive layer, the fifth insulation layer is located between the second conductive layer and the second semiconductor layer, the sixth insulation layer is located between the second semiconductor layer and the third conductive layer, the seventh insulation layer is located between the third conductive layer and the fourth conductive layer, the eighth insulation layer and the first planarization layer are located between the fourth conductive layer and the fifth conductive layer, the first planarization layer is located on a side of the eighth insulation layer away from the substrate, and the second planarization layer is located on a side of the fifth conductive layer away from the substrate.

In an exemplary implementation, as shown in FIG. 6, there is a parasitic capacitance between an active layer of an oxide transistor located in a second semiconductor layer (e.g. an active layer of the first transistor and an active layer of the second transistor) of a pixel circuit of a sub-pixel and the first scan signal line Gate1 located in the first conductive layer, and is referred to as a parasitic capacitance of the sub-pixel.

In an exemplary implementation, the parasitic capacitance of different sub-pixels is different. For example, parasitic capacitance of a red sub-pixel and a green sub-pixel may be the same, and may be different from parasitic capacitance of a blue sub-pixel. According to the present disclosure, the parasitic capacitance of different sub-pixels can be designed differently, such that data ranges of different sub-pixels can be balanced, a black state voltage can be adjusted, and the display effect of the display substrate can be improved.

In an exemplary implementation, different parasitic capacitance of different sub-pixels can be achieved by having different overlapping areas between the first scan signal lines located in the first conductive layer and the active layers of the oxide transistors, located in the second semiconductor layer, (e.g. the active layer of the first transistor and the active layer of the second transistor) in the pixel circuits of the different sub-pixels.

In an exemplary implementation, the display substrate may further include a light emitting structure layer located on a side of the drive structure layer away from the substrate. The light emitting structure layer may include a light emitting device.

Exemplary description is made below through a manufacturing process for a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition. The coating may be any one or more of spray coating, spin coating, and inkjet printing. The etching may be any one or more of dry etching and wet etching, which is not limited in the disclosure herein. A “thin film” refers to a layer of thin film made of a certain material on a substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film is a dimension of the film in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

FIGS. 10 to 26 are schematic diagrams of a manufacturing process for a display substrate according to an exemplary embodiment. FIGS. 10 to 26 are illustrated by taking sub-pixels in two rows and four columns as an example. As shown in FIGS. 10 to 26, a manufacturing process for a display substrate according to an exemplary embodiment may include following acts.

(1) A pattern of a light shielding layer is formed, including sequentially depositing a first insulation thin film and a light shielding thin film on a substrate, and patterning the light shielding thin film by a patterning process to form a first insulation layer covering the substrate and a pattern of a light shielding layer on the first insulation layer, as shown in FIG. 10, which is a schematic diagram after forming the pattern of the light shielding layer.

In an exemplary implementation, as shown in FIG. 10, the light shielding layer may include, at least, a light shielding structure located in at least one sub-pixel.

In an exemplary implementation, as shown in FIG. 10, all the light shielding structures are connected with each other to form an integral structure. Light shielding structures of adjacent sub-pixels located in a same row are disposed symmetrically with respect to a virtual straight line extending along the second direction D2, and light shielding structures of all sub-pixels located in a same column are the same.

In an exemplary implementation, as shown in FIG. 10, the light shielding structure may include a light shielding portion 10, a first light shielding connection portion 11, a second light shielding connection portion 12, a third light shielding connection portion 13, and a fourth light shielding connection portion 14. The light shielding section 10, the first light shielding connection portion 11, the second light shielding connection portion 12, the third light shielding connection portion 13, and the fourth light shielding connection portion 14 are connected with each other to form an integral structure.

In an exemplary implementation, as shown in FIG. 10, the first light shielding connection portion 11 and the second light shielding connection portion 12 are arranged along a second direction D2. In the second direction D2, the first light shielding connection portion 11 of the sub-pixel may be located on a side of the light shielding portion 10 close to sub-pixels in an upper row, and the second light shielding connection portion 12 of the sub-pixel may be located on a side of the light shielding portion 10 close to sub-pixels in a lower row. In a first direction D1 the third light shielding connection portion 13 and the fourth light shielding connection portion 14 of the sub-pixel are located on different sides of the light shielding portion 10. When the third light shielding connection portion 13 of the sub-pixel may be located on a side of the light shielding portion 10 close to the sub-pixels in the upper column, the fourth light shielding connection portion 14 of the sub-pixel may be located on a side of the light shielding portion 10 close to the sub-pixels in the lower column. When the third light shielding connection portion 13 of the sub-pixel may be located on a side of the light shielding portion 10 close to the sub-pixels in the lower column, the fourth light shielding connection portion 14 of the sub-pixel may be located on a side of the light shielding portion 10 close to the sub-pixels in the upper column.

In an exemplary implementation, as shown in FIG. 10, the light shielding portion 10 may be of a shape of rectangle, corners of the rectangle may be chamfered.

In an exemplary implementation, as shown in FIG. 10, the first light shielding connection portion 11 and the second light shielding connection portion 12 may be of a shape of strip extending along the second direction D2. The third light shielding connection portion 13 and the fourth light shielding connection portion 14 may be of a shape of strip extending along the first direction D1.

In an exemplary implementation, as shown in FIG. 10, the first light shielding connection portion of the sub-pixel is connected with a second light shielding connection portion of a sub-pixel located in an upper row and a same column, and the second light shielding connection portion of the sub-pixel is connected with a first light shielding connection portion of a sub-pixel located in a lower row and the same column. The third light shielding connection portion of the sub-pixel is connected with a third light shielding connection portion of one adjacent sub-pixel in a same row, and the fourth light shielding connection portion of the sub-pixel is connected with a fourth light shielding connection portion of another adjacent sub-pixel in the same row.

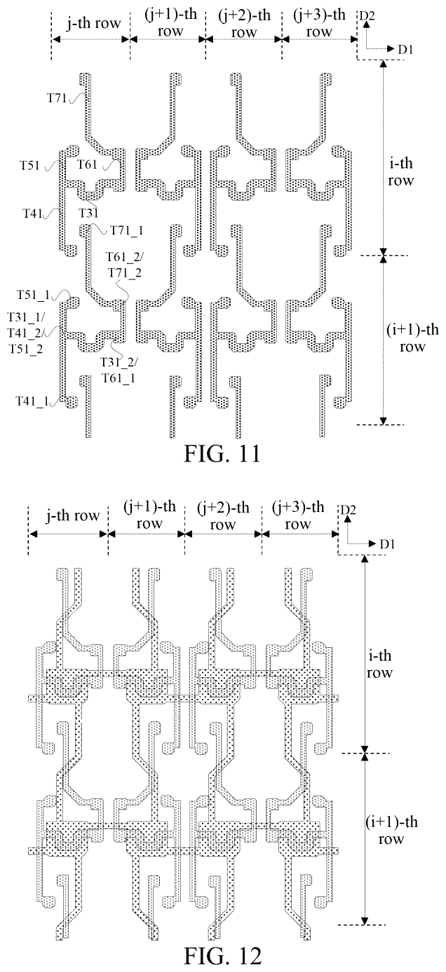

(2) A pattern of a first semiconductor layer is formed. In an exemplary implementation, forming the pattern of the first semiconductor layer may include sequentially depositing a second insulation thin film and a first semiconductor thin film on the substrate, patterning the first semiconductor thin film by a patterning process to form a second insulation layer covering the light shielding layer and a pattern of a first semiconductor layer on the second insulation layer, as shown in FIGS. 11 and 12, FIG. 11 is a schematic diagram of the pattern of the first semiconductor layer, and FIG. 12 is a schematic diagram after forming the pattern of the first semiconductor layer.

In an exemplary implementation, as shown in FIGS. 11 and 12, the pattern of the first semiconductor layer may include, at least, an active layer T31 of a third transistor, an active layer T41 of a fourth transistor, an active layer T51 of a fifth transistor, an active layer T61 of a sixth transistor, and an active layer T71 of a seventh transistor, which are located in at least one sub-pixel.

In an exemplary implementation, as shown in FIGS. 11 and 12, the active layer T31 of the third transistor to the active layer T71 of the seventh transistor are connected with each other to form an integral structure.

In an exemplary implementation, as shown in FIGS. 11 and 12, the active layers T31 of the third transistors to the active layers T71 of the seventh transistors of adjacent sub-pixels are symmetrically disposed with respect to a virtual straight line extending along the second direction D2.

In an exemplary implementation, as shown in FIGS. 11 and 12, in the first direction D1, the active layer T41 of the fourth transistor and the active layer T51 of the fifth transistor may be located on a same side of the active layer T31 of the third transistor in the sub-pixel, the active layer T61 of the sixth transistor may be located on another side of the active layer T31 of the third transistor in the sub-pixel, and the active layer T61 of the sixth transistor and the active layer T41 of the fourth transistor may be located on different sides of the active layer T31 of the third transistor in the sub-pixel. In the second direction D2, an active layer T51 of a fifth transistor, an active layer T61 of a sixth transistor and an active layer T71 of a seventh transistor in a sub-pixel in an i-th row may be located on a side of the active layer T31 of the third transistor in the sub-pixel away from a sub-pixel in an (i+1)-th row, and an active layer T41 of a fourth transistor in the sub-pixel in the i-th row may be located on a side of the active layer T31 of the third transistor in the sub-pixel in the i-th row close to the sub-pixel in the (i+1)-th row.

In an exemplary implementation, as shown in FIGS. 11 and 12, the active layer T31 of the third transistor may be in an inverted “Ω” shape. The active layer T41 of the fourth transistor, the active layer T51 of the fifth transistor, and the active layer T61 of the sixth transistor may be in an “I” shape. The active layer T71 of the seventh transistor may in of an “L” shape.

In an exemplary implementation, as shown in FIG. 12, an orthographic projection of the light shielding portion on the substrate is overlapped, at least partially, with an orthographic projection of the active layer T31 of the third transistor on the substrate. Orthographic projections of the first, second, third and fourth light shielding connection portions on the substrate are not overlapped with an orthographic projection of any of the active layer T21 of the second transistor, the active layer T31 of the third transistor and the active layer T71 of the seventh transistor on the substrate.

In an exemplary implementation, an active layer of each transistor may include a first region, a second region, and a channel region located between the first region and the second region. In an exemplary implementation, a first region T31_1 of the active layer 13 of the third transistor may also serve as a second region T41_2 of the active layer T41 of the fourth transistor and a second region T51_2 of the active layer T51 of the fifth transistor, a second region T31_2 of the active layer T31 of the third transistor may also serve as a first region T61_1 of the active layer T61 of the sixth transistor, a second region T61_2 of the active layer T61 of the sixth transistor may serve as a second region T71_2 of the active layer T71 of the seventh transistor. A first region T41_1 of the active layer T41 of the fourth transistor, a first region T51_1 of the active layer T51 of the fifth transistor and a first region T71_1 of the active layer T71 of the seventh transistor may be disposed separately.

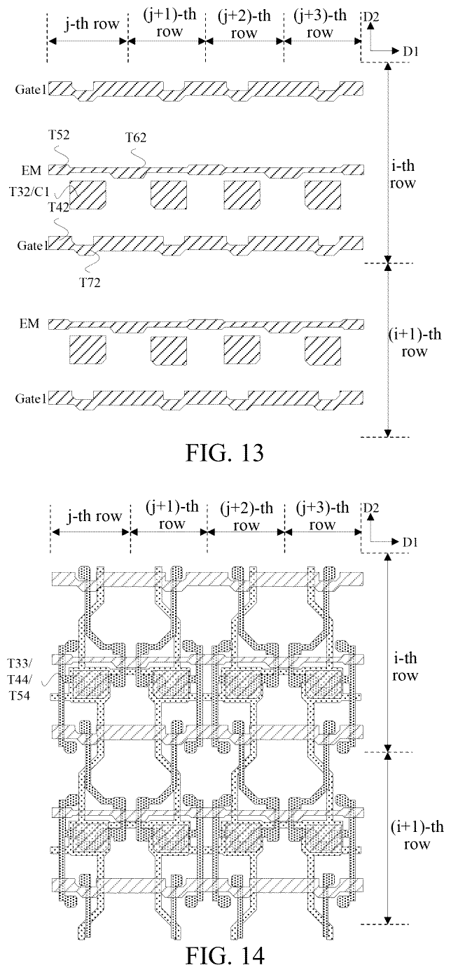

(3) A pattern of a first conductive layer is formed. In an exemplary implementation, forming the pattern of the first conductive layer may include: sequentially depositing a third insulation thin film and a first conductive thin film on the substrate on which the aforementioned patterns are formed, and the first conductive thin film is patterned through a patterning process to form a third insulation layer that covers the pattern of the first semiconductor layer and a pattern of a first conductive layer disposed on the third insulation layer, as shown in FIGS. 13 and 14, wherein FIG. 13 is a schematic diagram of the pattern of the first conductive layer, and FIG. 14 is a schematic diagram after the pattern of the first conductive layer is formed. In an exemplary implementation, the first conductive layer may be referred to as a first gate metal (GATE1) layer.

In an exemplary implementation, as shown in FIGS. 13 and 14, the pattern of the first conductive layer may include, at least, a first scan signal line Gate1, a light emitting signal line EM, and a first plate C1 located in a capacitor of at least one sub-pixel.

In an exemplary implementation, first plates C1 of pixel circuits of adjacent sub-pixels are disposed symmetrically with respect to a virtual straight line extending along the second direction D2.

In an exemplary implementation, the first plate C1 may be of a shape of rectangle in which corners may be chamfered. An orthographic projection of the first plate C1 on the substrate is overlapped, at least partially, with the orthographic projection of the active layer of the third transistor on the substrate. In an exemplary implementation, the first plate C1 may also serve as a plate of the storage capacitor and a gate electrode T32 of the third transistor T3.

In an exemplary implementation, the first scan signal line Gate1 may be in a shape of line in which a main portion extends along the first direction X. A first scan signal line Gate1 connected to a sub-pixel in an i-th row may be located on a side of the first plate C1 of a capacitor of the sub-pixel close to the sub-pixels in the (i+1)-th row. A region where the first scan signal line Gate1 is overlapped with the active layer of the fourth transistor in the sub-pixel may serve as a gate electrode T42 of the fourth transistor, and a region where the first scan signal line Gate1 is overlapped with the active layer of the seventh transistor in the sub-pixel may serve as a gate electrode T72 of the seventh transistor.

In an exemplary implementation, the light emitting signal line EM may be in a shape of line in which a main portion extends along the first direction D1, the light emitting signal line EM may be located on a side of the first plate C1 in the sub-pixel away from the sub-pixels in the (i+1)-th row, a region where the light emitting signal line EM is overlapped with the active layer of the fifth transistor in the sub-pixel serves as a gate electrode T52 of the fifth transistor, and a region where the light emitting signal line EM is overlapped with the active layer of the sixth transistor in the sub-pixel serves as a gate electrode T62 of the sixth transistor.

In an exemplary implementation, both of the first scan signal line Gate1 and the light emitting signal line EM may be in a design of equal width, or may be in a design of non-equal widths, may be straight lines, or may be bend lines, which may not only facilitate the layout of the pixel structure, but also reduce the parasitic capacitance between the signal lines, which is not limited in the present disclosure.

In an exemplary implementation, after the pattern of the first conductive layer is formed, conductor transformation treatment may be performed on the first semiconductor layer by using the first conductive layer as a shield. A region of the first semiconductor layer, which is shielded by the first conductive layer, forms a channel region of the first transistor T3 to the seventh transistor T7, and a region of the first semiconductor layer, which is not shielded by the first conductive layer, is made to be conductive. That is, the first region and the second region of the third transistor to the seventh active layer are made to be conductive. The first region T31_1 of the active layer T31 of the third transistor (i.e. the second region T41_2 of the active layer T41 of the fourth transistor and the second region T51_2 of the active layer T51 of the fifth transistor) after conductor transformation treatment is performed may also serve as the a first electrode T33 of the third transistor (i.e. a second electrode T44 of the fourth transistor, and a second electrode T54 of the fifth transistor).

In an exemplary implementation, a gate electrode T32 of the third transistor is provided across the active layer of the third transistor, the gate electrode T42 of the fourth transistor is provided across the active layer of the fourth transistor, the gate electrode T52 of the fifth transistor is provided across the active layer of the fifth transistor, the gate electrode T62 of the sixth transistor is provided across the active layer of the sixth transistor, and the gate electrode T72 of the seventh transistor is provided across the active layer of the seventh transistor. That is, an extension direction of a gate electrode of at least one transistor is perpendicular to an extension direction of the active layers.

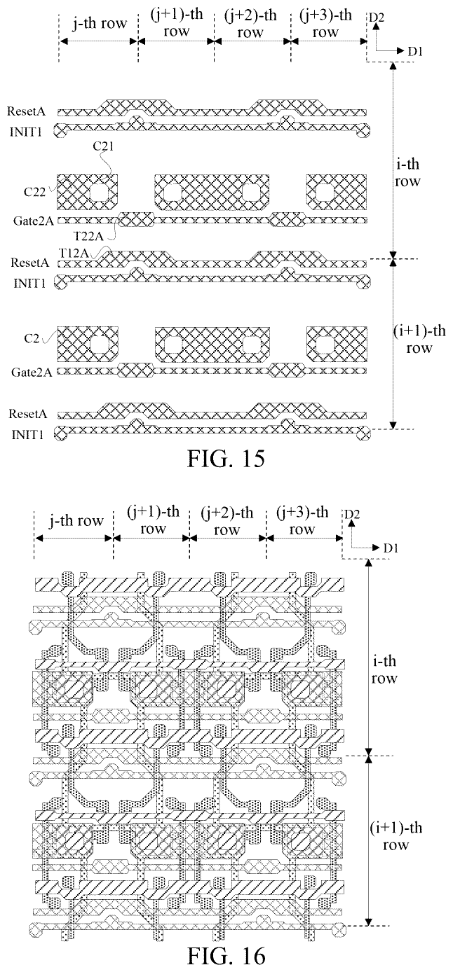

(4) A pattern of a second conductive layer is formed, which includes: depositing a fourth insulation thin film and a second conductive thin film sequentially on the substrate on which the aforementioned patterns are formed, patterning the fourth insulation thin film and the second conductive thin film by a patterning process to form a fourth insulation layer and a pattern of a second conductive layer on the fourth insulation layer, as shown in FIGS. 15 and 16, wherein FIG. 15 is a schematic diagram of the second conductive layer pattern, and FIG. 16 is a schematic diagram after the pattern of the second conductive layer is formed. In an exemplary implementation, the second conductive layer may be referred to as a second gate metal (GATE2) layer.

In an exemplary implementation, as shown in FIGS. 15 and 16, the pattern of the second conductive layer may include, at least, a first initial signal line INIT1, a first sub-reset signal line ResetA of a reset signal line, a first sub-scan signal line Gate2A of a second scan signal line, and a second plate C2 located in a capacitor of at least one sub-pixel.

In an exemplary implementation, as shown in FIGS. 15 and 16, second plates C2 of pixel circuits of adjacent sub-pixels located in a same row are disposed symmetrically with respect to a virtual straight line extending along a second direction D2.

In an exemplary implementation, as shown in FIG. 15, the second plate C2 may include a main portion C21 and a connection portion C22 connected with each other, wherein the connection portion C22 of the sub-pixel is located on a side of the main portion C21 of the sub-pixel close to a previous column or a next column of sub-pixels.

In an exemplary embodiment, as shown in FIG. 15, a contour of the main portion C21 may be in a shape of rectangle in which corners may be chamfered, an orthographic projection of the main portion C21 on the substrate is overlapped, at least partially, with the orthographic projection of the first plate on the substrate. The second plate may serve as another plate of the capacitor, and the first plate C1 and the second plate C2 form a capacitor of the pixel circuit. The main portion C21 is provided with an opening which may be in a shape of rectangle, and may be located in the middle as shown in FIG. 20, so as to form an annular structure as shown in FIG. 20. The opening exposes a fourth insulation layer covering the first plate, and an orthographic projection of the first plate on the substrate contains an orthographic projection of the opening on the substrate. In an exemplary implementation, the opening exposes the first plate, so that a second electrode of the first transistor (i.e. a second electrode of the second transistor) formed subsequently is connected with the first plate.

In an exemplary implementation, as shown in FIG. 15, a contour of the connection portion C22 may be rectangular.

In an exemplary implementation, a length of the main portion C21 along the second direction may be equal to a length of the connection portion C22 along the second direction.

In an exemplary implementation, a second plate C2 of any sub-pixel is spaced away from a second plate C2 of an adjacent sub-pixel located in a same row, and is connected with a second plate of another adjacent sub-pixel located in the same row to form an integral structure. For example, a second plate of a sub-pixel in an i-th row and a j-th column is spaced away from a second plate of a sub-pixel in an i-th row and a (j+1)-th column, a second plate of a sub-pixel in an i-th row and a (j+2)-th column is spaced away from a second plate of a sub-pixel in an i-th row and a (j+3)-th column, and a second plate of a sub-pixel in an i-th row and a (j+1)-th column is connected with a second plate of a sub-pixel in an i-th row and a (j+2)-th column. According to the present disclosure, second plates of a part of adjacent sub-pixels located in a same row are connected with each other, which can ensure the display uniformity of the display substrate to a certain extent.

In an exemplary implementation, the first initial signal line INIT1 may be in a shape of line in which a main portion extends along the first direction X. A first initial signal line INIT1 connected to a sub-pixel in the i-th row may be located on a side of the second plate C2 of the sub-pixel close to the sub-pixels in the (i+1)-th row. For the same sub-pixel, an orthographic projection of a first initial signal line INIT1 to which the sub-pixel is connected on the substrate is located on a side of the orthographic projection of the first sub-reset signal line ResetA of the reset signal line to which the sub-pixel is connected on the substrate away from the orthographic projection of the first plate of the sub-pixel on the substrate.

In an exemplary implementation, the first sub-reset signal line ResetA of the reset signal line may be in a shape of line in which a main portion extends along the first direction D1, the first sub-reset signal line ResetA may be located between the second plate C2 of the connected sub-pixel and the first initial signal line INIT1, and a region where the first sub-reset signal line ResetA is overlapped with the active layer of the subsequently formed first transistor of the sub-pixel serves as a first gate electrode T12A of the first transistor. For the same sub-pixel, the orthographic projection of the first sub-reset signal line ResetA to which the sub-pixel is connected on the substrate is located between an orthographic projection of a first scan signal line to which the sub-pixel is connected on the substrate and the orthographic projection of a first initial signal line INIT1 to which the sub-pixel is connected on the substrate.

In an exemplary implementation, the first sub-scan signal line Gate2A of the second scan signal line may be in a shape of line in which a main portion extends along the first direction D1, the first sub-scan signal line Gate2A of the second scan signal line may be located between the second plate C2 of the connected sub-pixel and the first sub-reset signal line ResetA of the reset signal line, and a region where the first sub-scan signal line Gate2A of the second scan signal line is overlapped with the active layer of the sequentially formed second transistor of the sub-pixel serves as a first gate electrode T22A of the second transistor. For the same sub-pixel, the orthographic projection of the first sub-scan signal line Gate2A, which is connected to the sub-pixel, on the substrate is located between the orthographic projection of the first plate of the sub-pixel on the substrate and the orthographic projection of the first scan signal line, which is connected to the sub-pixel, on the substrate.

In an exemplary implementation, the first initial signal line INIT1, the first sub-reset signal line ResetA of the reset signal line, and the first sub-scan signal line Gate2A of the second scan signal line may be in a design of equal width, or may be in a design of non-equal widths, may be straight lines, or may be bend lines, which may not only facilitate the layout of the pixel structure, but also reduce the parasitic capacitance between the signal lines, which is not limited in the present disclosure.

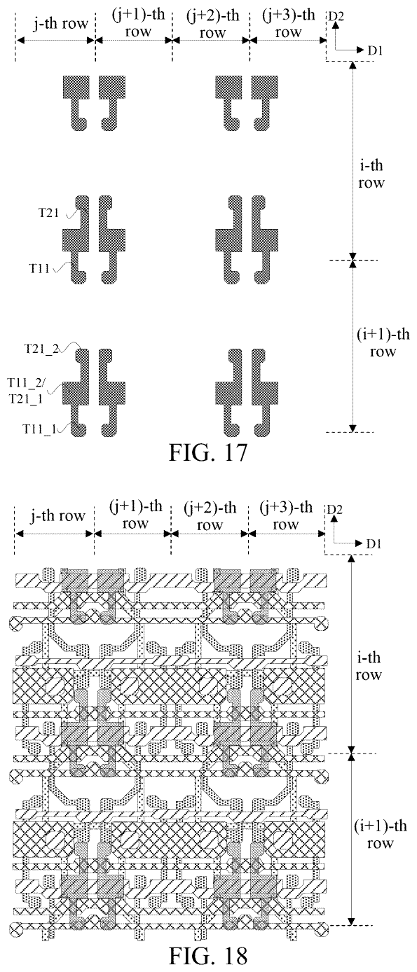

(5) A pattern of a second semiconductor layer is formed, which includes: on the substrate on which the aforementioned patterns are formed, sequentially depositing a fifth insulation thin film and a second semiconductor thin film, patterning the fifth insulation thin film and the second semiconductor thin film through a patterning process to form a fifth insulation layer and a pattern of a second semiconductor layer on the fifth insulation layer, as shown in FIGS. 17 and 18, wherein FIG. 17 is a schematic diagram of the pattern of the second semiconductor layer, and FIG. 18 is a schematic diagram after the pattern of the second semiconductor layer is formed.

In an exemplary implementation, as shown in FIGS. 17 and 18, the pattern of the second semiconductor layer may include, at least, an active layer T11 of a first transistor and an active layer T21 of a second transistor, located in at least one sub-pixel.

In an exemplary implementation, as shown in FIGS. 17 and 18, the active layer T11 of the first transistor to the active layer T21 of the second transistor are connected with each other to form an integral structure.

In an exemplary implementation, as shown in FIGS. 17 and 18, the active layers T11 of the first transistors and the active layers T21 of the second transistors of adjacent sub-pixels are symmetrically disposed with respect to a virtual straight line extending along the second direction D2.

In an exemplary implementation, as shown in FIGS. 17 and 18, in the second direction D2, active layers T21 of second transistors in sub-pixels in the row may be located on a side of active layers T11 of first transistors in the sub-pixel in the row close to sub-pixels in an upper row.

In an exemplary implementation, as shown in FIGS. 17 and 18, the active layer T11 of the first transistor and the active layer T21 of the second transistor may be in “I” shaped or “L” shaped.

In an exemplary implementation, as shown in FIGS. 17 and 18, for the same sub-pixel, an orthographic projection of the active layer T11 of the first transistor of the sub-pixel on the substrate is overlapped, at least partially, with the orthographic projection of the first sub-reset signal line of the reset signal line to which the sub-pixel is connected on the substrate, and the orthographic projection of the first initial signal line to which the sub-pixel is connected on the substrate.

In an exemplary implementation, as shown in FIGS. 17 and 18, for the same sub-pixel, an orthographic projection of the active layer T21 of the second transistor of the sub-pixel on the substrate is overlapped with an orthographic projection of the first sub-scan signal line of the second scan signal line to which the sub-pixel is connected on the substrate.

In an exemplary implementation, as shown in FIG. 17, an active layer of each transistor may include a first region, a second region and a channel region between the first region and the second region. In an exemplary implementation, a second region T11_2 of the active layer T11 of the first transistor may also serve as a first region T21_1 of the active layer T21 of the second transistor, and the first region T11_1 of the active layer T11 of the first transistor and the second region T21_2 of the active layer T21 of the second transistor may be separately disposed.

In an exemplary implementation, for the same sub-pixel, an orthographic projection of the second region T11_2 of the active layer T11 of the first transistor of the sub-pixel (i.e. the first region T21_1 of the active layer T21 of the second transistor) on the substrate is overlapped, at least partially, with the orthographic projection of the first scan signal line to which the sub-pixel is connected on the substrate.

In an exemplary implementation, the active layer T11 of the first transistor is disposed across the first gate electrode of the first transistor, and the active layer T21 of the second transistor is disposed across the first gate electrode of the second transistor.

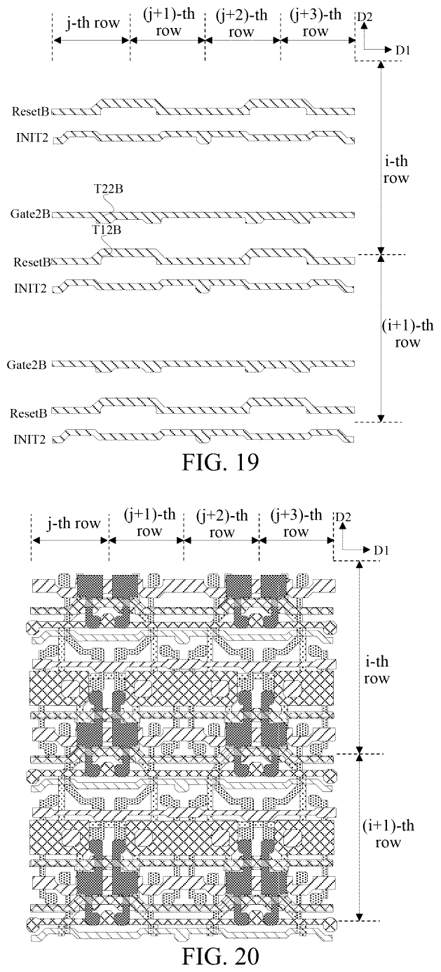

(6) A pattern of a third conductive layer is formed, which includes: depositing a sixth insulation thin film and a third conductive thin film sequentially on the substrate on which the aforementioned patterns are formed, patterning the sixth insulation thin film and the third conductive thin film by a patterning process to form a pattern of a sixth insulation layer and a pattern of a third conductive layer located on the sixth insulation layer, as shown in FIGS. 19 and 20, wherein FIG. 19 is a schematic diagram of the pattern of the third conductive layer, and FIG. 20 is a schematic diagram after the pattern of the third conductive layer is formed. In an exemplary implementation, the third conductive layer may be referred to as a third gate metal (GATE3) layer.

In an exemplary implementation, as shown in FIGS. 19 and 20, the pattern of the third conductive layer may include, at least, the second sub-reset signal line ResetB of the reset signal line, the second sub-scan signal line Gate2B of the second scan signal line, and the second initial signal line INIT2.

In an exemplary implementation, as shown in FIGS. 19 and 20, the second sub-reset signal line ResetB of the reset signal line may be in a shape of line in which a main portion extends along the first direction D1, an orthographic projection of the second sub-reset signal line ResetB of the reset signal line on the substrate is overlapped, at least partially, with the orthographic projection of the first sub-reset signal line of the reset signal line on the substrate, and is electrically connected with the first sub-reset signal line of the reset signal line.

In an exemplary embodiment, as shown in FIGS. 19 and 20, for the same sub-pixel, the orthographic projection of the second sub-reset signal line ResetB on the substrate is located between the orthographic projection of the first scan signal line on the substrate and the orthographic projection of the first initial signal line INIT1 on the substrate. A region where the second sub-reset signal line ResetB of the reset signal line is overlapped with the active layer of the first transistor of the sub-pixel serves as a second gate electrode T12B of the first transistor. The first gate electrode and the second gate electrode of the first transistor form a gate electrode of the first transistor.

In an exemplary implementation, as shown in FIGS. 19 and 20, the second sub-scan signal line Gate2B of the second scan signal line may be in a shape of line in which a main portion extends along the first direction D1, the orthographic projection of the second sub-scan signal line Gate2B of the second scan signal line on the substrate is overlapped, at least partially, with the orthographic projection of the first sub-scan signal line of the second scan signal line on the substrate, and is electrically connected with the first sub-scan signal line of the second scan signal line.

In an exemplary implementation, as shown in FIGS. 19 and 20, the orthographic projection of the second sub-scan signal line Gate2B on the substrate is located between the orthographic projection of the light emitting signal line on the substrate and the orthographic projection of the first scan signal line on the substrate. A region where the second sub-scan signal line Gate2B of the second scan signal line is overlapped with the active layer of the second transistor of the sub-pixel serves as a second gate electrode T22B of the second transistor. The first gate electrode and the second gate electrode of the second transistor form a gate electrode of the second transistor.

In an exemplary implementation, as shown in FIGS. 19 and 20, the second initial signal line INIT2 may be in a shape of line in which a main portion extends along the first direction D1. The orthographic projection of the second initial signal line INIT2 on the substrate is located between the orthographic projection of the first initial signal line on the substrate and the orthographic projection of the light emitting signal line on the substrate.

In an exemplary implementation, the second sub-reset signal line ResetB of the reset signal line, the second sub-scan signal line Gate2B of the second scan signal line and the second initial signal line INIT2 may be in a design of equal width, or may be in a design of non-equal widths, may be straight lines, or may be bend lines, which may not only facilitate the layout of the pixel structure, but also reduce the parasitic capacitance between the signal lines, which is not limited in the present disclosure.

In an exemplary implementation, after the pattern of the third conductive layer is formed, conductor transformation treatment may be performed on the second semiconductor layer by using the pattern of the third conductive layer as a shield. A region of the second semiconductor layer, which is shielded by the third conductive layer, forms a channel region of the first transistor to the second transistor, and a region of the second semiconductor layer, which is not shielded by the third conductive layer, is made to be conductive. That is, the first region and the second region of active layer of the first transistor and the active layer of the second transistor are made to be conductive.

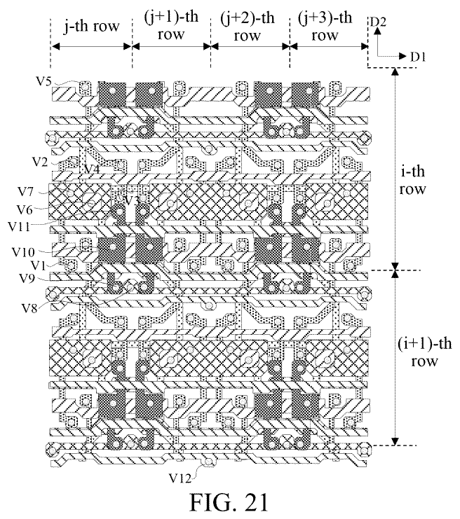

(7) A pattern of a seventh insulation layer is formed, which includes depositing a seventh insulation thin film on the substrate on which the aforementioned patterns are formed, and patterning the seventh insulation thin film by a patterning process to form a pattern of a seventh insulation layer covering the aforementioned patterns. The seventh insulation layer is opened with a pattern of a plurality of vias, as shown in FIG. 21, which is a schematic diagram after the pattern of the seventh insulation layer is formed.

In an exemplary implementation, as shown in FIG. 21, the plurality of vias of the seventh insulation layer include, at least, a first via V1, a second via V2, a third via V3, a fourth via V4, a fifth via V5, a sixth via V6, a seventh via V7, an eighth via V8, a ninth via V9, a tenth via V10, an eleventh via V11, and a twelfth via V12, which are located in at least one sub-pixel.

In an exemplary implementation, an orthographic projection of the first via V1 on the substrate is within a range of an orthographic projection of the first region of the active layer of the fourth transistor on the substrate, a sixth insulation layer, a fifth insulation layer, a fourth insulation layer and a third insulation layer within the first via V1 are etched away to expose a surface of the first region of the active layer of the fourth transistor, and the first via V1 is configured to connect a first electrode of the subsequently formed fourth transistor to the first region of the active layer of the fourth transistor through the via.

In an exemplary implementation, an orthographic projection of the second via V2 on the substrate is within a range of an orthographic projection of the first region of the active layer of the fifth transistor on the substrate. A sixth insulation layer, a fifth insulation layer, a fourth insulation layer, and a third insulation layer within the second via V2 are etched away to expose a surface of the first region of the active layer of the fifth transistor, and the second via V2 is configured such that a first electrode of the subsequently formed fifth transistor is connected to the first region of the active layer of the fifth transistor through the via.

In an exemplary implementation, an orthographic projection of the third via V3 on the substrate is within a range of an orthographic projection of the second region of the active layer of the third transistor (i.e. the first region of the active layer of the sixth transistor) on the substrate, a sixth insulation layer, a fifth insulation layer, a fourth insulation layer and a third insulation layer within the third via V3 are etched away to expose a surface of the second region of the active layer of the third transistor (i.e. the first region of the active layer of the sixth transistor), and the third via V3 is configured such that a second electrode of the second transistor (i.e. a second electrode of the third transistor and a first electrode of the sixth transistor) formed subsequently is connected to the second region of the active layer of the third transistor (i.e. the first region of the active layer of the sixth transistor) through the via.

In an exemplary implementation, an orthographic projection of the fourth via V4 on the substrate is within a range of an orthographic projection of the second region of the active layer of the sixth transistor (i.e. the second region of the active layer of the seventh transistor) on the substrate. A sixth insulation layer, a fifth insulation layer, a fourth insulation layer and a third insulation layer within the fourth via V4 are etched away to expose a surface of the second region of the active layer of the sixth transistor (i.e. the second region of the active layer of the seventh transistor T7), and the fourth via V4 is configured such that a second electrode of the sixth transistor T6 (i.e. the second electrode of the seventh transistor T7) formed subsequently is connected to the second region of the active layer of the sixth transistor (i.e. the second region of the active layer of the seventh transistor) through the via.

In an exemplary implementation, an orthographic projection of the fifth via V5 on the substrate is within a range of an orthographic projection of the first region of the active layer of the seventh transistor on the substrate. A sixth insulation layer, a fifth insulation layer, a fourth insulation layer, and a third insulation layer within the fifth via V5 are etched away to expose a surface of the first region of the active layer of the seventh transistor, and the fifth via V5 is configured such that a first initial connection portion (i.e. the first electrode of the seventh transistor) formed subsequently is connected to the first region of the active layer of the seventh transistor through the via.

In an exemplary implementation, an orthographic projection of the sixth via V6 on the substrate is within a range of the orthographic projection of the first plate of the capacitor on the substrate. A sixth insulation layer, a fifth insulation layer and a fourth insulation layer within the sixth via V6 are etched away to expose a surface of the first plate of the capacitor, and the sixth via V6 is configured such that the second electrode of the first transistor T1 (i.e. the first electrode of the second transistor) formed subsequently is connected to the first plate of the capacitor through the via.

In an exemplary implementation, an orthographic projection of the seventh via V7 on the substrate is within a range of the orthographic projection of the second plate of the capacitor on the substrate. A sixth insulation layer and a fifth insulation layer within the seventh via V7 are etched away to expose a surface of the second plate of the capacitor, and the seventh via V7 is configured such that the first electrode of the fifth transistor formed subsequently is connected to the second plate of the capacitor through the via.

In an exemplary implementation, an orthographic projection of the eighth via V8 on the substrate is within a range of an orthographic projection of the first initial signal line on the substrate. A sixth insulation layer and a fifth insulation layer within the eighth via V8 are etched away to expose a surface of the first initial signal line, and the eighth via V8 is configured such that the first electrode of the first transistor formed subsequently is connected to the first initial signal line through the via.

In an exemplary implementation, an orthographic projection of the ninth via V9 on the substrate is located within a range of an orthographic projection of the first region of the active layer of the first transistor on the substrate. A sixth insulation layer within the ninth via V9 is etched away to expose a surface of the first region of the active layer of the first transistor, and the ninth via V9 is configured such that the first electrode of the first transistor formed subsequently is connected to the first region of the active layer of the first transistor through the via.

In an exemplary implementation, an orthographic projection of the tenth via V10 on the substrate is within a range of an orthographic projection of the second region of the active layer of the first transistor (i.e. the first region of the active layer of the second transistor) on the substrate. A sixth insulation layer within the tenth via V10 is etched away to expose a surface of the second region of the active layer of the first transistor (i.e. the first region of the active layer of the second transistor), and the tenth via V10 is configured such that the second electrode of the first transistor (i.e. the first electrode of the second transistor) formed subsequently is connected to the second region of the active layer of the first transistor (i.e. the first region of the active layer of the second transistor) through the via.

In an exemplary implementation, an orthographic projection of the eleventh via V11 on the substrate is within a range of an orthographic projection of the second region of the active layer of the second transistor on the substrate, a sixth insulation layer within the eleventh via V11 is etched away to expose a surface of the second region of the active layer of the second transistor, and the eleventh via V11 is configured such that the second electrode of the second transistor (i.e. the first electrode of the sixth transistor) formed subsequently is connected to the second region of the active layer of the second transistor through the via.

In an exemplary implementation, an orthographic projection of the twelfth via V12 on the substrate is within a range of an orthographic projection of the second initial signal line on the substrate. A surface of the second initial signal line is exposed. The twelfth via V12 is configured such that a second initial connection line formed subsequently is connected to the second initial signal line through the via.

In an exemplary implementation, as shown in FIG. 21, an eighth via V8 of two adjacent sub-pixels is a same via. The eighth via V8 of the two adjacent sub-pixels is the same via, which can reduce a quantity of vias in the display substrate and simplify the manufacturing process of the display substrate.

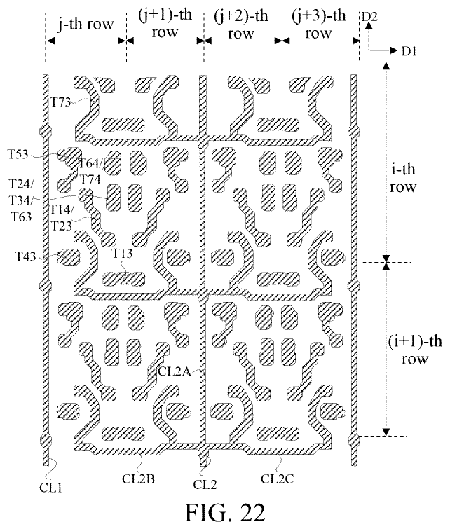

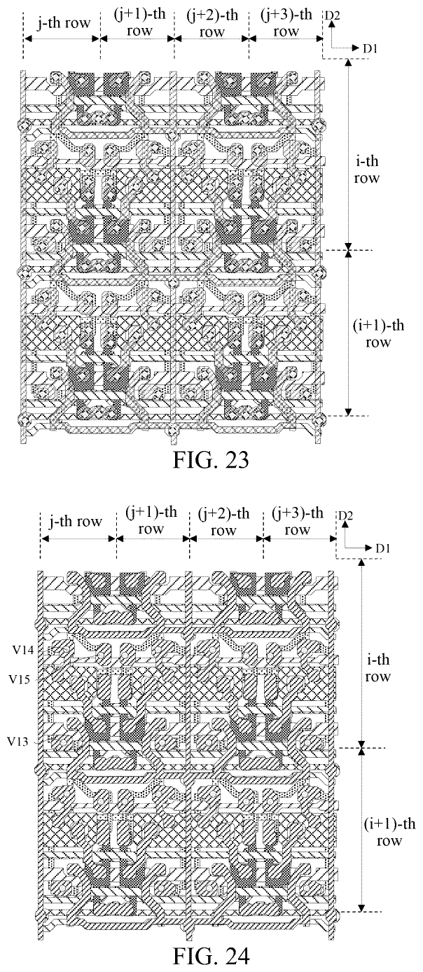

(8) A pattern of a fourth conductive layer is formed, which includes depositing a fourth conductive thin film on the substrate on which the aforementioned patterns are formed, and patterning the fourth conductive thin film by a patterning process to form a pattern of a fourth conductive layer, as shown in FIGS. 22 and 23, wherein FIG. 22 is a schematic diagram of the pattern of the fourth conductive layer, and FIG. 23 is a schematic diagram after the pattern of the fourth conductive layer is formed. In an exemplary implementation, the fourth conductive layer may be referred to as a first source drain metal (SD1) layer.

In an exemplary implementation, as shown in FIGS. 22 and 23, the pattern of the fourth conductive layer may include, at least, the first initial connection line CL1, the second initial connection line CL2, and a first electrode T13 of the first transistor, a second electrode T14 of the first transistor, a first electrode T23 of the second transistor, a second electrode T24 of the second transistor, a second electrode T34 of the third transistor, a first electrode T43 of the fourth transistor, a first electrode T53 of the fifth transistor, a first electrode T63 of the sixth transistor, a second electrode T64 of the sixth transistor, a first electrode T73 of the seventh transistor, and a second electrode T74 of the seventh transistor located in at least one sub-pixel.

In an exemplary implementation, first electrodes and second electrodes of a plurality of transistors of adjacent sub-pixels are symmetrically disposed with a virtual straight line extending along the second direction D2.

In an exemplary implementation, as shown in FIGS. 22 and 23, adjacent sub-pixels located in a same row as the sub-pixel includes a first adjacent sub-pixel and a second adjacent sub-pixel, the first electrode of the first transistor of the sub-pixel is integrated with a first electrode of a first transistor of the first adjacent sub-pixel, and is spaced away from a first electrode of a first transistor of the second adjacent sub-pixel. The first adjacent sub-pixel is a sub-pixel in a column previous to the sub-pixel, and the second adjacent sub-pixel is a sub-pixel in a column next to the sub-pixel. For example, a first electrode of a first transistor located in an i-th row and a j-th column is integrated with a first electrode of a first transistor located in the i-th row and a (j+1)-th column, a first electrode of a first transistor located in the i-th row and a (j+2)-th column is integrated with a first electrode of a first transistor located in the i-th row and a (j+3)-th column, and a first electrode of a first transistor located in a column j+1 and row i is spaced away from the first electrode of the first transistor located in the i-th row and the (j+2)-th column.

In an exemplary implementation, as shown in FIGS. 22 and 23, the first electrode T13 of the first transistor is in a shape of strip extending along the first direction D1. The first electrode T13 of the first transistor is connected with the first region of the active layer of the first transistor through the ninth via, and is electrically connected with the first initial signal line through the eighth via.

In an exemplary implementation, as shown in FIGS. 22 and 23, the second electrode T14 of the first transistor is integrated with the first electrode T23 of the second transistor, which is in a shape of line extending, at least partially, along the second direction D2. The second electrode T14 of the first transistor (i.e. the first electrode T23 of the second transistor) is connected with the first plate of the capacitor through the sixth via, and is connected with the second region of the active layer of the first transistor (i.e. the first region of the active layer of the second transistor) through the tenth via.

In an exemplary implementation, as shown in FIGS. 22 and 23, the second electrode T24 of the second transistor, the second electrode T34 of the third transistor, and the first electrode T63 of the sixth transistor are in an integral structure that is in a block shape. The second electrode T24 of the second transistor (i.e. the second electrode T34 of the third transistor and the first electrode T63 of the sixth transistor) is connected to the second region of the active layer of the third transistor (i.e. the first region of the active layer of the sixth transistor) through the third via, and is connected to the second region of the active layer of the second transistor through the eleventh via.

In an exemplary implementation, as shown in FIGS. 22 and 23, the first electrode T43 of the fourth transistor is in a block shape. The first electrode T43 of the fourth transistor is connected to the first region of the active layer of the fourth transistor through the first via.

In an exemplary implementation, as shown in FIGS. 22 and 23, the first electrode T53 of the fifth transistor may be in a bend line shape. The first electrode T53 of the fifth transistor is connected to the first region of the active layer of the fifth transistor through the second via, and is electrically connected to the second plate of the capacitor through the seventh via.

In an exemplary implementation, as shown in FIGS. 22 and 23, the second electrode T64 of the sixth transistor (i.e. the second electrode T74 of the seventh transistor) is in a block shape, and the second electrode T64 of the sixth transistor (i.e. the second electrode T74 of the seventh transistor) is connected to the second region of the active layer of the sixth transistor (i.e. the second region of the active layer of the seventh transistor) through the fourth via.

In an exemplary implementation, as shown in FIGS. 22 and 23, the first electrode T73 of the seventh transistor is in a shape of bend line extending, at least partially, along the second direction D2. The first electrode T73 of the seventh transistor is connected to the first region of the active layer of the seventh transistor through the fifth via. An orthographic projection of the first electrode T73 of the seventh transistor on the substrate is partially overlapped with the orthographic projections of the first initial signal line, the reset signal line, and the first scan signal line on the substrate.

In an exemplary implementation, as shown in FIGS. 22 and 23, the first initial connection line CL1 is in a shape of line extending along the second direction D2. The first initial connection line CL1 is connected to the first initial signal line through the eighth via.

In an exemplary implementation, as shown in FIGS. 22 and 23, an orthographic projection of the first initial connection line CL1 on the substrate is overlapped, at least partially, with the orthographic projection of the second plate of the capacitor on the substrate, and is not overlapped with the orthographic projection of the reset signal line on the substrate.

In an exemplary implementation, as shown in FIGS. 22 and 23, the second initial connection line CL2 includes a signal body line CL2A, a first signal connection portion CL2B, and a second signal connection portion CL2C. The signal body line CL2A is in a shape of line extending along the second direction D2. The first signal connection portion CL2B and the second signal connection portion CL2C are located on opposite sides of the signal body line CL2A, and are connected with the signal body line CL2A, respectively. The first signal connection portion CL2B and the second signal connection portion CL2C extend along the first direction D1. The signal body line CL2A is connected with the second initial signal line through the twelfth via.

In an exemplary implementation, the first signal connection portion CL2B is integrated with first electrodes of seventh transistors of two sub-pixels located in a same row, between the signal body line and an adjacent first initial connection line adjacent to the second initial connection line CL2. The second signal connection portion CL2C is integrated with first electrodes of seventh transistors of two sub-pixels located in the same row, between the signal body line and another adjacent first initial connection line adjacent to the second initial connection line CL2.

In an exemplary implementation, orthographic projections of the first signal connection portion CL2B and the second signal connection portion CL2C on the substrate are overlapped, at least partially, with the orthographic projection of the second initial signal line on the substrate. For example, the orthographic projection of the second initial signal line on the substrate covers the orthographic projections of the first signal connection portion CL2B and the second signal connection portion CL2C on the substrate.

In an exemplary implementation, the first initial connection lines CL1 and the second initial connection lines CL2 are alternately arranged along the first direction D1. That is, one second initial connection line CL2 is located between two first initial connection lines CL1. The two first initial connection lines CL1 pass through the signal body line of the second initial connection line CL2 along a centerline in the second direction D2.

(9) A pattern of a first planarization layer is formed, which includes depositing an eighth insulation thin film on the substrate on which the aforementioned patterns are formed, patterning the eighth insulation thin film by a patterning process to form an eighth insulation layer, coating a first planarization thin film on the eighth insulation layer, and patterning the first planarization thin film by a patterning process to form a pattern of a first planarization layer covering the aforementioned patterns. The first planarization layer is opened with a pattern of a plurality of vias, as shown in FIG. 24, which is a schematic diagram after the pattern of the first planarization layer is formed.

In an exemplary implementation, as shown in FIG. 24, the plurality of vias include, at least, a thirteenth via V13 to a fifteenth via V15 located in at least one sub-pixel.

In an exemplary implementation, as shown in FIG. 24, an orthographic projection of the thirteenth via V13 on the substrate is within a range of an orthographic projection of the first electrode of the fourth transistor on the substrate, an eighth insulation layer within the thirteenth via V13 is etched away to expose a surface of the first electrode of the fourth transistor, and the thirteenth via V13 is configured such that a data signal line formed subsequently is connected to the first electrode of the fourth transistor through the via.

In an exemplary implementation, as shown in FIG. 24, an orthographic projection of the fourteenth via V14 on the substrate is within a range of an orthographic projection of the first electrode of the fifth transistor on the substrate. An eighth insulation layer within the fourteenth via V14 is etched away to expose a surface of the first electrode of the fifth transistor, and the fourteenth via V14 is configured such that a first power supply line formed subsequently is connected to the first electrode of the fifth transistor through the via.

In an exemplary implementation, as shown in FIG. 24, an orthographic projection of the fifteenth via V15 on the substrate is within a range of an orthographic projection of the second electrode of the sixth transistor (i.e. the second electrode of the seventh transistor) on the substrate. A sixth insulation layer within the fifteenth via V15 is etched away to expose a surface of the second electrode of the sixth transistor (i.e. the second electrode of the seventh transistor), and the fifteenth via V15 is configured such that a connection electrode formed subsequently is connected to the second electrode of the sixth transistor (i.e. the second electrode of the seventh transistor) through the via.

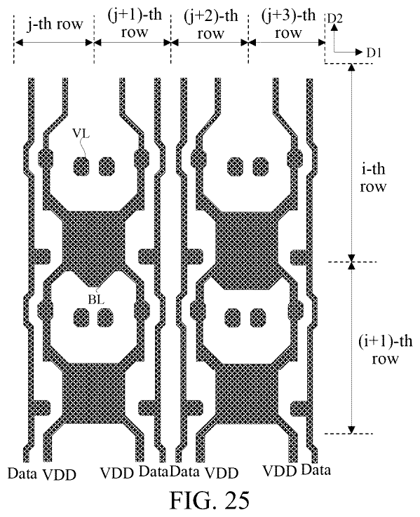

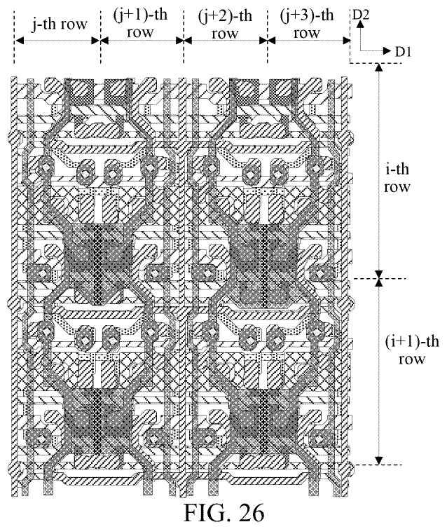

(10) A pattern of a fifth conductive layer is formed, which includes depositing a fifth conductive thin film on the substrate on which the aforementioned patterns are formed, and patterning the fifth conductive thin film by a patterning process to form a pattern of a fifth conductive layer, as shown in FIGS. 25 and 26, wherein FIG. 25 is a schematic diagram of the pattern of the fifth conductive layer, and FIG. 26 is a schematic diagram after the pattern of the fifth conductive layer is formed. In an exemplary implementation, the fifth conductive layer may be referred to as a second source-drain metal (SD2) layer.

In an exemplary implementation, as shown in FIGS. 25 and 26, the pattern of the fifth conductive layer may include, at least, a data signal line Data, a first power supply line VDD, a planarization portion BL, and a connection electrode VL located in at least one sub-pixel.

In an exemplary implementation, a plurality of data signal lines Data are arranged along the first direction D1, and a plurality of first power supply lines VDD are arranged along the first direction D1.

In an exemplary implementation, a first power supply line VDD connecting to the sub-pixel is located on a side of the data signal line Data connecting to the sub-pixel close to a next column of sub-pixels. First power supply lines VDD connecting to adjacent sub-pixels is disposed symmetrically with respect to a virtual straight line along the second direction D2. Data signal lines Data connecting to adjacent sub-pixels are disposed symmetrically with respect to a virtual straight line along the second direction D2.

In an exemplary implementation, the data signal line Data and the first power supply line VDD, to which the sub-pixel is connected, are located on a same side of the connection electrode of the sub-pixel, and the data signal line Data is located on a side of the first power supply line VDD away from the connection electrode.

In an exemplary implementation, as shown in FIGS. 25 and 26, the data signal line Data may be in a shape of line extending, at least partially, along the second direction D2.

In an exemplary implementation, as shown in FIGS. 25 and 26, the first power supply line VDD may be in a shape of line extending, at least partially, along the second direction D2. For example, the first power supply line VDD may be in a bend line shape.

In an exemplary implementation, as shown in FIGS. 25 and 26, the first power supply line VDD is connected with one adjacent power supply line, and is spaced away from another adjacent power supply line. Two data signal lines Data are provided between the two first power supply lines spaced away. Alternatively, first power supply lines connected to adjacent sub-pixels may be spaced away.

In an exemplary implementation, an orthographic projection of the signal body line of the second initial connection line on the substrate is located between orthographic projections of two adjacent data signal lines on the substrate. An orthographic projection of the first initial connection line on the substrate is located between orthographic projections of two adjacent data signal lines on the substrate.

In an exemplary implementation, as shown in FIGS. 25 and 26, a planarization portion BL is disposed between two adjacent first power supply lines VDD, and is connected to the two adjacent first power supply lines VDD.

In an exemplary implementation, as shown in FIGS. 25 and 26, the planarization portion BL may be in a shape of polygon, which may be a square or other shape.

In an exemplary implementation, as shown in FIGS. 25 and 26, an orthographic projection of the planarization portion BL on the substrate may be overlapped, at least partially, with the orthographic projection of the active layer of the first transistor and the active layer of the second transistor on the substrate.

In an exemplary implementation, as shown in FIGS. 25 and 26, the orthographic projection of the planarization portion BL on the substrate is overlapped, at least partially, with the orthographic projections of the reset signal line, the first scan signal line, and the second scan signal line on the substrate.

In an exemplary implementation, as shown in FIGS. 25 and 26, a plurality of annular regions are included in a structure formed by a first power supply line connected to two adjacent columns of sub-pixels, and two planarization portions of adjacent rows of sub-pixels. At least two annular regions are in different shapes.

In an exemplary implementation, the annular region may have a symmetrical structure or an asymmetrical structure, and FIGS. 25 and 26 are illustrated by taking the annular region having a symmetrical structure as an example.

In an exemplary implementation, adjacent planarization portions located in a same row may be symmetrically disposed, or may be asymmetrically disposed, which may be determined according to a shape of a first electrode of a connected light emitting device. FIGS. 25 and 26 illustrate an example in which adjacent planarization portions located in a same row may be symmetrically disposed.

In an exemplary implementation, as shown in FIG. 26, an orthographic projection of the connection electrodes on the substrate is located in an annular region formed by first power supply lines of two adjacent columns of sub-pixels and two planarization portions of adjacent rows of sub-pixels.

In an exemplary implementation, as shown in FIGS. 25 and 26, a connection electrode VL may be in a block shape. The connection electrode is configured to connect with a first electrode of a light emitting device formed subsequently. Connection electrodes connected to first electrodes of different light emitting devices may be in different shapes.

In an exemplary implementation, as shown in FIGS. 25 and 26, the data signal line Data is electrically connected to the first electrode of the fourth transistor through the thirteenth via. The first power supply line VDD is connected to the first electrode of the fifth transistor through the fourteenth via, and the connection electrode VL is connected to the second electrode of the sixth transistor (i.e. the second electrode of the seventh transistor) through the fifteenth via.

(11) A pattern of a second planarization layer is formed, which includes: coating a second planarization thin film on the substrate on which the aforementioned patterns are formed, and patterning the second planarization thin film by a patterning process to form a pattern of a second planarization layer covering the aforementioned patterns.

So far, the drive structure layer has been manufactured on the substrate. In a plane parallel to the display substrate, the drive structure layer may include a plurality of pixel circuits, and the drive structure layer is connected with the first scan signal line, the second scan signal line, the light emitting signal line, the first initial signal line, the second initial signal line, the reset signal line, the data signal line and the first power supply line. The drive structure layer may be disposed on the substrate. The drive structure layer may include the first insulation layer, the light shielding layer, the second insulation layer, the first semiconductor layer, the third insulation layer, the first conductive layer, the fourth insulation layer, the second conductive layer, the fifth insulation layer, the second semiconductor layer, the sixth insulation layer, the third conductive layer, the seventh insulation layer, the fourth conductive layer, an eighth insulation layer, the first planarization layer, the fifth conductive layer and the second planarization layer disposed in sequence on the substrate.

In an exemplary implementation, the first semiconductor layer may be an amorphous silicon layer or a polysilicon layer.

In an exemplary implementation, the second semiconductor layer may be a metal oxide layer. The metal oxide layer may be made of an oxide containing indium and tin, an oxide containing tungsten and indium, an oxide containing tungsten, indium and zinc, an oxide containing titanium and indium, an oxide containing titanium, indium and tin, an oxide containing indium and zinc, an oxide containing silicon, indium and tin, or an oxide containing either indium and zinc or gallium and zinc. The metal oxide layer may be mono-layered, double-layered or multi-layered.

In an exemplary implementation, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be have a single-layer structure or a multi-layer composite structure, such as Mo/Cu/Mo.

In an exemplary implementation, the first insulation layer, the second insulation layer, the third insulation layer, the fourth insulation layer, the fifth insulation layer, the sixth insulation layer, the seventh insulation layer and the eighth insulation layer may be made of any one or more of silicon oxide (SiOx), silicon nitride (SiNx) and silicon oxynitride (SiON), and may be a single layer, a plurality of layers, or a composite layer.

In an exemplary implementation, the first planarization layer and the second planarization layer may be made of an organic material, such as resin or the like.

In an exemplary implementation, after the drive structure layer is manufactured, a light emitting structure layer is manufactured on the drive structure layer, and a manufacturing process of the light emitting structure layer may include following acts.

(12) A pattern of a sixth conductive layer is formed. In an exemplary implementation, forming the pattern of the sixth conductive layer may include depositing a sixth conductive thin film on the substrate on which the aforementioned patterns are formed, patterning the sixth conductive thin film by a patterning process to form a sixth conductive layer disposed on the second planarization layer, wherein the sixth conductive layer includes, at least, a plurality of first electrode patterns.

In an exemplary implementation, the pattern of the sixth conductive layer may include a plurality of first electrode patterns. The plurality of first electrode patterns may include the first electrode of the first light emitting device, the first electrode of the second light emitting device, the first electrode of the third light emitting device, and the first electrode of the fourth light emitting device, wherein the first electrode of the first light emitting device is located in the red sub-pixel emitting red light, the first electrode of the second light emitting device is located in the blue sub-pixel emitting blue light, the first electrode of the third light emitting device is located in a first green sub-pixel emitting green light, and the first electrode of the fourth light emitting device is located in a second green sub-pixel emitting green light.

In an exemplary implementation, the first electrode of the first light emitting device and the first electrode of the second light emitting device may be alternately disposed along the second direction, and the first electrode of the third light emitting device and the first electrode of the fourth light emitting device may be alternately disposed along the second direction. Alternatively, the first electrode of the first light emitting device and the first electrode of the second light emitting device may be alternately disposed along the first direction, and the first electrode of the third light emitting device and the first electrode of the fourth light emitting device may be alternately disposed along the first direction.

In an exemplary implementation, the first electrode of the first light emitting device, the first electrode of the second light emitting device, the first electrode of the third light emitting device, and the first electrode of the fourth light emitting device may respectively pass through a via that exposes the connection electrode of the sub-pixel where the light emitting devices are located, to be connected to the connection electrode of the sub-pixel where the light emitting devices are located.

In an exemplary implementation, four sub-pixels in a pixel unit may have a same or different anode shapes and areas.

In an exemplary implementation, at least one of the first electrode of the first light emitting device, the first electrode of the second light emitting device, the first electrode of the third light emitting device, and the first electrode of the fourth light emitting device may include an anode main portion and an anode connection portion connected with each other, wherein the anode connection portion is connected with the connection electrode.

In an exemplary implementation, the first electrode of the first light emitting device may include a first anode main portion and a first anode connection portion connected with each other, the first anode main portion may be in a shape of rectangle in which corners may be provided with arc-shaped chamfers, and the first anode connection portion may be in a strip shape. In an exemplary implementation, the first electrode of the second light emitting device may include a second anode main portion and a second anode connection portion connected with each other, the second anode main portion may be in a shape of rectangle in which corners may be provided with arc-shaped chamfers, and the second anode connection portion may be in a strip shape. In an exemplary implementation, the first electrode of the third light emitting device may include a third anode main portion and a third anode connection portion connected with each other, the third anode main portion may be in a shape of rectangle in which corners may be provided with arc-shaped chamfers, and the third anode connection portion may be in a strip shape. In an exemplary implementation, the first electrode of the fourth light emitting device may include a fourth anode main portion and a fourth anode connection portion connected with each other, the fourth anode main portion may be in a shape of rectangle in which corners may be provided with arc-shaped chamfers, and the fourth anode connection portion may be in a strip shape.

In an exemplary implementation, the sixth conductive layer has a single-layer structure, such as Indium Tin Oxide (ITO) or Indium Zinc Oxide (IZO), or may have a multi-layer composite structure, such as ITO/Ag/ITO.

(13) A pattern of a cathode conductive layer is formed. In an exemplary implementation, forming the cathode conductive layer may include coating a pixel definition thin film on the substrate on which the aforementioned patterns are formed, depositing the pixel definition thin film on the substrate on which the aforementioned patterns are formed, patterning the pixel definition thin film by a patterning process to form a pattern of a pixel definition layer exposing the pattern of the sixth conductive layer, coating an organic luminescent material on the substrate on which the pattern of the pixel definition layer is formed, patterning the organic luminescent material by a patterning process to form a pattern of an organic structure layer, depositing a cathode conductive thin film on the substrate on which the pattern of the organic material layer is formed, and patterning the cathode conductive thin film by a patterning process to form the cathode conductive layer.

In an exemplary implementation, a subsequent manufacturing process may include forming a package structure layer on the cathode conductive layer, wherein the package structure layer may include a first encapsulation layer, a second encapsulation layer and a third encapsulation layer which are stacked. The first encapsulation layer and the third encapsulation layer may be made of an inorganic material, the second encapsulation layer may be made of an organic material, and the second encapsulation layer is disposed between the first encapsulation layer and the third encapsulation layer to ensure that external water vapor cannot enter the light emitting structure layer.

In an exemplary implementation, the organic structure layer may include at least an organic light emitting layer of the light emitting device.

In an exemplary implementation, the cathode conductive layer may include, at least, cathodes of a plurality of light emitting devices.

In an exemplary implementation, the cathode layer may be made of a metal material, such as any one or more of argentum (Ag), copper (Cu), aluminum (Al), and molybdenum (Mo), or a conductive alloy material of the above metals, such as an Aluminum Neodymium alloy (AlNd) or a Molybdenum Niobium alloy (MoNb), and may have a single-layer structure or a multi-layer composite structure, such as Mo/Cu/Mo. For example, the fourth conductive layer may have a three-layer stacked structure formed of titanium, aluminum, and titanium.

The display substrate according to the embodiment of the present disclosure may be applied to a display product with any resolution.

A display apparatus is further provided in an embodiment of the present disclosure, including a display substrate.

The display substrate is the display substrate according to any of the aforementioned embodiments, and has similar implementation principles and implementation effects, which is not repeated here.

In an exemplary implementation, the display apparatus may be any product or component with a display function, such as a liquid crystal panel, electronic paper, an OLED panel, an Active-Matrix Organic Light Emitting Diode (AMOLED) panel, a mobile phone, a tablet computer, a television, a display, a notebook computer, a digital photo frame, or a navigator.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure, but not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A display substrate, comprising: a substrate, and a plurality of sub-pixels, a plurality of first signal lines and a plurality of second signal lines provided on the substrate, wherein:
a sub-pixel of the plurality of sub-pixels comprises a pixel circuit electrically connected with the first signal lines, the first signal lines comprise at least one initial signal line, and second signal lines comprises at least one initial connection line; the initial signal line is extended along a first direction, the initial connection line is extended along a second direction, and the first direction is intersected with the second direction; and
the at least one initial signal line is in a one-to-one correspondence with the at least one initial connection line, and the initial signal line is electrically connected with the corresponding initial connection line.

2. The display substrate of claim 1, wherein the at least one initial signal line comprises a first initial signal line and a second initial signal line, wherein the second initial signal line is located at a side of the first initial signal line away from the substrate.

3. The display substrate of claim 2, further comprising a plurality of reset signal lines extending, at least partially, along the first direction, wherein
an orthographic projection of the first initial signal line on the substrate is located between an orthographic projection of the second initial signal line on the substrate and an orthographic projection of a reset signal line on the substrate, and is not overlapped with the orthographic projection of the second initial signal line on the substrate and the orthographic projection of the reset signal line on the substrate.

4. The display substrate of claim 2, further comprising: a plurality of light emitting signal lines extending, at least partially, along the first direction, wherein
an orthographic projection of the second initial signal line on the substrate is located between an orthographic projection of the first initial signal line on the substrate and an orthographic projection of a light emitting signal line on the substrate, and is not overlapped with the orthographic projection of the first initial signal line on the substrate and the orthographic projection of the light emitting signal line on the substrate.

5. The display substrate of claim 4, wherein:
the at least one initial connection line comprises a plurality of first initial connection lines and a plurality of second initial connection lines, wherein the first initial connection lines and the second initial connection lines are disposed in a same layer, the plurality of first initial connection lines are arranged along the first direction, and the plurality of second initial connection lines are arranged along the first direction;
the first initial connection lines and the second initial connection lines are alternately arranged along the first direction, two first initial connection lines passes through, along a centerline of the second direction, a signal body line of a second initial connection line located between the two first initial connection lines; and
a first initial connection line is electrically connected with the first initial signal line through a via, and a second initial connection line is electrically connected with the second initial signal line through a via.

6. The display substrate of claim 5, wherein:
the pixel circuit comprises a capacitor, and the capacitor comprises a first plate and a second plate, wherein the second plate of the capacitor is located at a side of the first plate of the capacitor away from the substrate; and
the orthographic projection of the first initial signal line on the substrate is overlapped, at least partially, with an orthographic projection of the second plate of the capacitor on the substrate.

7. The display substrate of claim 6, wherein:
the second initial connection line comprises a signal body line, a plurality of first signal connection portions, and a plurality of second signal connection portions; wherein the signal body line is extended along the second direction, the first signal connection portions and the second signal connection portions are extended along the first direction, the first signal connection portions and the second signal connection portions are connected with the signal body line, respectively, and the signal body line is connected with the second initial signal line; and
the first signal connection portions and the second signal connection portions are located at opposite sides of the signal body line, and are symmetrically disposed with respect to the signal body line.

8. The display substrate of claim 7, wherein an orthographic projection of the signal body line on the substrate is overlapped, at least partially, with the orthographic projection of the second plate of the capacitor on the substrate.

9. The display substrate of claim 7, wherein orthographic projections of the first signal connection portions and the second signal connection portions on the substrate are overlapped, at least partially, with the orthographic projection of the second initial signal line on the substrate, and are not overlapped with an orthographic projection of a reset signal line on the substrate.

10. The display substrate of claim 1, wherein pixel structures of pixel circuits of adjacent sub-pixels located in a same row are symmetrically disposed with respect to a virtual straight line extending along the second direction.

11. The display substrate of claim 7, further comprising a plurality of data signal lines extending along the second direction, wherein:
data signal lines connected to adjacent sub-pixels are disposed symmetrically with respect to a virtual straight line extending along the second direction;
an orthographic projection of the first initial connection line on the substrate or the orthographic projection of the signal body line of the second initial connection line on the substrate is located between orthographic projections of two adjacent data signal lines on the substrate.

12. The display substrate of claim 7, further comprising a plurality of first scan signal lines extended, at least partially, along the first direction, wherein:
an orthographic projection of a reset signal line on the substrate is located between an in orthographic projection of a first scan signal line on the substrate and the orthographic projection of the first initial signal line on the substrate;
the reset signal line comprises a first sub-reset signal line and a second sub-reset signal line electrically connected with each other; and
the first sub-reset signal line is disposed in a same layer as the first initial signal line, the second sub-reset signal line is disposed in a same layer as the second initial signal line, and an orthographic projection of the first sub-reset signal line on the substrate is overlapped, at least partially, with an orthographic projection of the second sub-reset signal line on the substrate.

13. The display substrate of claim 12, further comprising: a plurality of second scan signal lines extending, at least partially, along the first direction, wherein:
an orthographic projection of a second scan signal line on the substrate is located between the orthographic projection of the first scan signal line on the substrate and the orthographic projection of the light emitting signal line on the substrate;
the second scan signal line comprises a first sub-scan signal line and a second sub-scan signal line electrically connected with each other; and
the first sub-scan signal line is disposed in a same layer as the first initial signal line, the second sub-scan signal line is disposed in a same layer as the second initial signal line, and an orthographic projection of the first sub-scan signal line on the substrate is overlapped, at least partially, with an orthographic projection of the second sub-scan signal line on the substrate.

14. The display substrate of claim 1, further comprising: a plurality of first power supply lines and a plurality of planarization portions, wherein:
the sub-pixel further comprises a light emitting device, the light emitting device comprises a first electrode, and the pixel circuit comprises an oxide transistor;
the planarization portions are disposed between adjacent first power supply lines, and connected with the adjacent first power supply lines;
orthographic projections of the planarization portions on the substrate is overlapped, at least partially, with orthographic projections of a reset signal line, a first scan signal line, a second scan signal line, an active layer of the oxide transistor and the first electrode of the light emitting device on the substrate; and
at least one of the orthographic projections of the planarization portions on the substrate is overlapped, at least partially, with an orthographic projection of a first initial signal line on the substrate.

15. The display substrate of claim 14, wherein a plurality of annular regions are formed between the plurality of first power supply lines and the plurality of planarization portions; and at least two annular regions are in different shapes.

16. The display substrate of claim 14, comprising a display region and a non-display region, wherein:
the display substrate further comprises a third signal line located in the non-display region, the sub-pixels, the first signal lines and the second signal lines are located in the display region, the third signal line comprises at least one initial power supply line, the initial power supply line is extended, at least partially, along the second direction; and
the at least one initial power supply line is in one-to-one correspondence with the at least one initial signal line, and the initial power supply line is electrically connected with the corresponding initial signal line.

17. The display substrate of claim 16, wherein the display region comprises a first side and a second side disposed opposite to each other, and the third signal line is located on at least one of the first side and the second side of the display region.

18. The display substrate of claim 15, further comprising: a drive structure layer disposed on the substrate, wherein:
the drive structure layer comprises a first semiconductor layer, a first conductive layer, a second conductive layer, a second semiconductor layer, a third conductive layer, a fourth conductive layer and a fifth conductive layer which are stacked in sequence;
the first conductive layer comprises, at least, a first scan signal line, a light emitting signal line, and a first plate located in a capacitor of at least one sub-pixel;
the second conductive layer comprises, at least, the first initial signal line, a first sub-reset signal line of the reset signal line, a first sub-scan signal line of the second scan signal line, and a second plate located in the capacitor of the at least one sub-pixel;
the third conductive layer comprises, at least, a second sub-reset signal line of the reset signal line, a second sub-scan signal line of the second scan signal line, and a second initial signal line;
the fourth conductive layer comprises, at least, a first initial connection line and a second initial connection line; and
the fifth conductive layer comprises, at least, data signal lines, the first power supply lines, and the planarization portions.

19. A display apparatus, comprising the display substrate of claim 1.

20. The display substrate of claim 3, further comprising: a plurality of light emitting signal lines extending, at least partially, along the first direction, wherein an orthographic projection of the second initial signal line on the substrate is located between an orthographic projection of the first initial signal line on the substrate and an orthographic projection of a light emitting signal line on the substrate, and is not overlapped with the orthographic projection of the first initial signal line on the substrate and the orthographic projection of the light emitting signal line on the substrate.
